(19) United States
(12) Patent Application Publication
(10) Pub. No.: US 2025/0311422 A1
(43) Pub. Date: Oct. 2, 2025

(54) SEMICONDUCTOR DEVICE

(71) Applicant: Samsung Electronics Co., Ltd., Suwon-si (KR)

(72) Inventors: Junghan Lee, Suwon-si (KR); Jisoo Park, Suwon-si (KR); Byungsung Kim, Suwon-si (KR); Kwanyoung Chun, Suwon-si (KR)

(21) Appl. No.: 19/013,212

(22) Filed: Jan. 8, 2025

(30) Foreign Application Priority Data
Mar. 27, 2024 (KR) 10-2024-0041528

(51) Int. Cl. H10D 84/90; H03K 19/20

(52) U.S. Cl. CPC H10D 84/975; H10D 84/953; H03K 19/20

(57) ABSTRACT

A semiconductor device includes first cell transistors on a first cell region, second cell transistors on a second cell region spaced apart from the first cell region in a first direction, a first wiring group electrically connecting at least some of the first cell transistors to each other, a second wiring group electrically connecting at least some of the second cell transistors to each other. The first and second cell regions may be equal in size. The first wiring group may include a first through via and first wirings contacting upper and lower portions of the first through via. The second wiring group may include a second through via and second wirings contacting upper and lower portions of the second through via. Each of the first and second through vias may be on a center of a first interface region between the first and second cell regions.

### CROSS-REFERENCE TO RELATED APPLICATION

This application claims priority under 35 USC § 119 to Korean Patent Application No. 10-2024-0041528, filed on Mar. 27, 2024, in the Korean Intellectual Property Office (KIPO), the contents of which are incorporated by reference herein in their entirety.

### BACKGROUND

The present inventive concept relates generally to a semiconductor device, and, more particularly, relates to a semiconductor device including a plurality of transistors arranged in a vertical direction and including an interconnection structure connecting the plurality of transistors.

When a plurality of transistors are arranged in the vertical direction in a semiconductor device, a diameter and a depth of wirings electrically connecting the transistors may be increased. Accordingly, a horizontal area required to form the wirings may be increased. Therefore, manufacturing of highly integrated semiconductor devices may be difficult.

### SUMMARY

Various example embodiments provide a highly integrated semiconductor device.

According to some example embodiments, there is provided a semiconductor device. The semiconductor device may include a plurality of transistors arranged in a vertical direction and an interconnection structure connecting the plurality of transistors.

According to some example embodiments, there is provided a semiconductor device. The semiconductor device may include first P-type transistors on a lower support layer of a first cell region, first N-type transistors over the first P-type transistors, second P-type transistors P3 on the lower support layer of a second cell region spaced apart from the first cell region in a first direction, second N-type transistors over the second P-type transistors, an insulation pattern structure on a first interface region between the first and second cell regions, a first through via passing through the insulation pattern structure, a second first through via passing through the insulation pattern structure, a first wiring group electrically connected to the first through via, and a second wiring group electrically connected to the second through via. The first through via may be on a center of the first interface region in the first direction. The second through via may be on a center of the first interface region in the first direction, and the second through via may be spaced apart from the first through via in a second direction perpendicular to the first direction. The first wiring group may electrically connect one of the first N-type transistors and one of the first P-type transistors to each other. The second wiring group may electrically connect one of the second N-type transistors and one of the second P-type transistors.

According to some example embodiments, there is provided a semiconductor device. The semiconductor device may include a lower support layer including a first cell region, a second cell region, and a first interface region between the first and second cell regions, a second interface region outside the first cell region, and a third interface region outside the second cell region, first cell transistors including first P-type transistors and first N-type transistors, second cell transistors including second P-type transistors and second N-type transistors, a first through via on the first interface region, a second through via on the first interface region, a first wiring group connected to the first through via, and a second wiring group connected to the second through via. The first P-type transistors may be on the first cell region of the lower support layer, and the first N-type transistors may be spaced apart from the first P-type transistors in a vertical direction. The second P-type transistors may be on the second cell region of the lower support layer. The second N-type transistors may be spaced apart from the second P-type transistors in the vertical direction. An upper surface of the first through via may be higher than an upper surface of a gate structure of an uppermost first cell transistor. A bottom of the first through via may be lower than a bottom of a gate structure of a lowermost first cell transistor. The second through via may have a shape the same as a shape of the first through via. The first wiring group may electrically connect at least ones of the first cell transistors to each other. The second wiring group may electrically connect at least ones of the second cell transistors to each other.

According to some example embodiments, there is provided a semiconductor device. The semiconductor device may include first cell transistors on a first cell region, second cell transistors on a second cell region being spaced apart from the first cell region in a first direction, a first wiring group electrically connecting at least ones of the first cell transistors to each other, a second wiring group electrically connecting at least ones of the second cell transistors to each other. The second cell region may have a size the same as a size of the first cell region. The first wiring group may include a first through via and first wirings contacting an upper portion and a lower portion of the first through via. The second wiring group may include a second through via and second wirings contacting an upper portion and a lower portion of the second through via. Each of the first through via and the second through via may be on a center of a first interface region between the first cell region and the second cell region in the first direction.

According to example embodiments, the semiconductor device may include the first through via electrically connected to a portion of the first cell transistors constituting the first cell and the second through via electrically connected to a portion of the second cell transistors constituting the second cell. The first through via and the second through via may be at a first interface region between the first and second cell regions. In addition, the first through via and the second through via may be on a center of the first interface region in the first direction. As the first through via and the second through via included in different cells are on the first interface region, a horizontal area required to form the semiconductor device including the first cell and the second cell may be decreased.

### BRIEF DESCRIPTION OF THE DRAWINGS

Various example embodiments will be more clearly understood from the following detailed description taken in conjunction with the accompanying drawings. FIGS. 1 to 25 represent various non-limiting, example embodiments as described herein, wherein like reference numerals (when used) indicate corresponding elements throughout the several views, and wherein:

FIG. 1 is a circuit diagram of each of a plurality of cells in a semiconductor device according to example embodiments;

FIG. 2A is a schematic plan view of each of a plurality of cells in a semiconductor device according to example embodiments;

FIG. 2B is a schematic plan view of each of a plurality of cells in a semiconductor device according to example embodiments;

FIG. 3 is a schematic perspective view of a first cell in a semiconductor device according to example embodiments;

FIG. 4 is a schematic perspective view of a second cell in a semiconductor device according to example embodiments;

FIG. 5 is a schematic plan view illustrating connection wirings in each of a plurality of cells of a semiconductor device according to example embodiments;

FIG. 6 is a schematic perspective view illustrating connection wirings in each of a plurality of cells of a semiconductor device according to example embodiments;

FIGS. 7 to 9 are schematic cross-sectional views of semiconductor devices according to example embodiments, respectively;

FIG. 10 is a flowchart illustrating a method of manufacturing a semiconductor device according to example embodiments;

FIGS. 11 to 19 are schematic plan views illustrating intermediate processes in a method of manufacturing a semiconductor device according to example embodiments;

FIG. 20 is a circuit diagram of each of a plurality of cells of a semiconductor device according to example embodiments;

FIG. 21 is a schematic plan view illustrating connection wirings of each of a plurality of cells of a semiconductor device according to example embodiments;

FIG. 22 is a schematic perspective view of a first cell of a semiconductor device according to example embodiments;

FIG. 23 is a schematic perspective view of a second cell of a semiconductor device according to example embodiments;

FIG. 24 is a schematic perspective view illustrating connection wirings of each of a plurality of cells of a semiconductor device according to example embodiments; and

FIG. 25 is a schematic cross-sectional view of a semiconductor device according to example embodiments.

### DETAILED DESCRIPTION

Hereinafter, various example embodiments will be described in detail with reference to the accompanying drawings. Hereinafter, a direction parallel to an upper surface of a substrate is referred to as a first direction (i.e., first horizontal direction), and a direction parallel to the upper surface of the substrate and perpendicular to the first direction is referred to as a second direction (i.e., second horizontal direction). Additionally, a direction perpendicular to the upper surface of the substrate is referred to as a vertical direction.

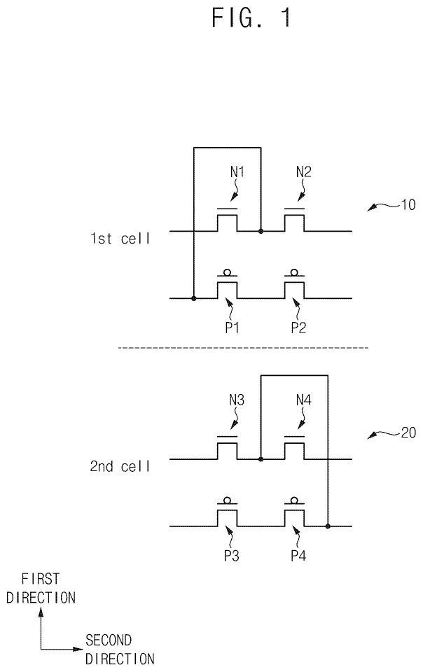

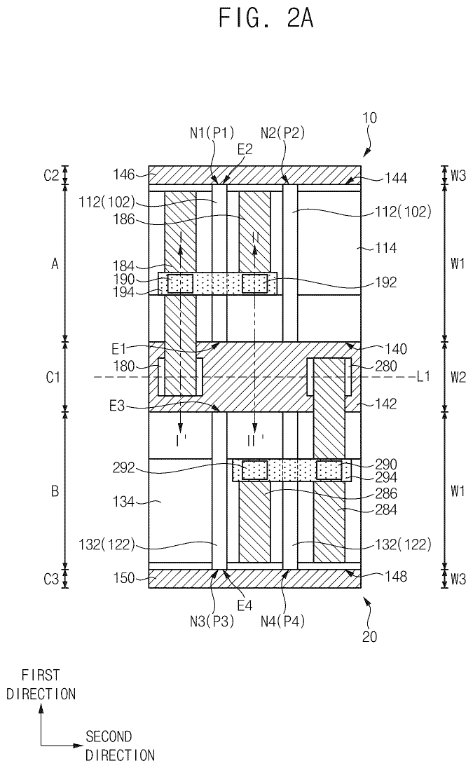

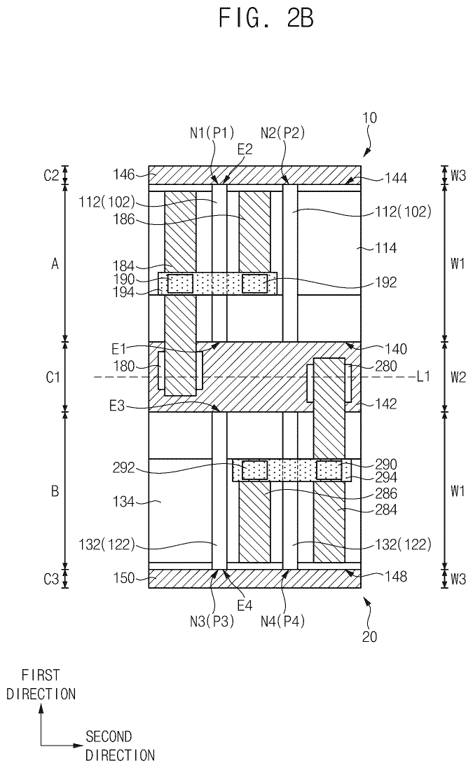

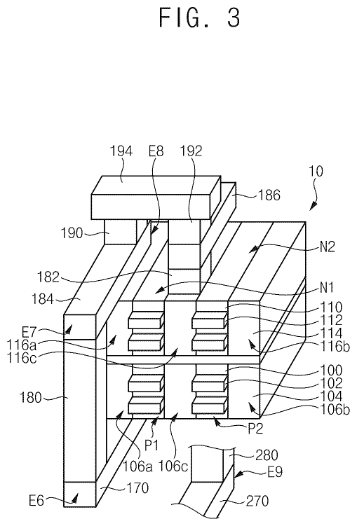

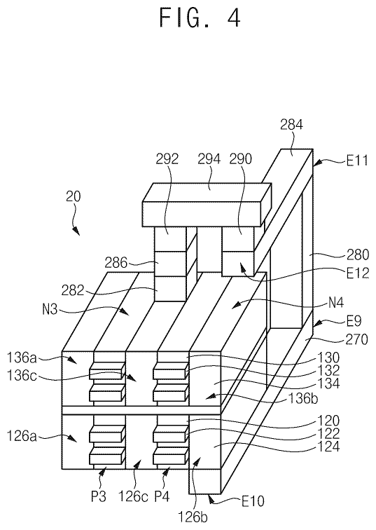

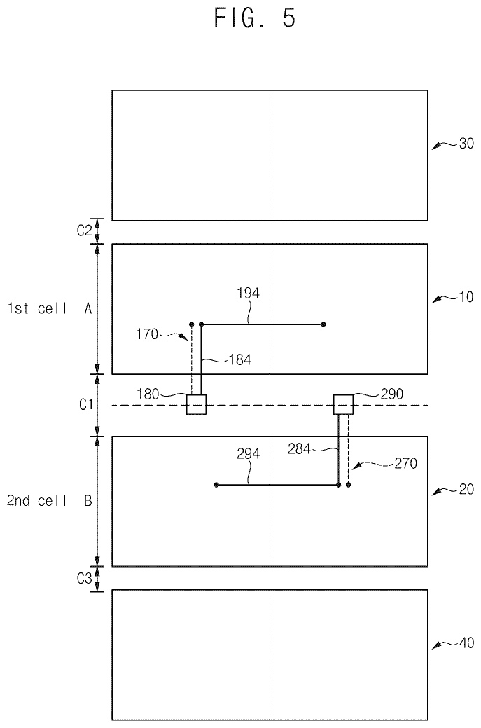

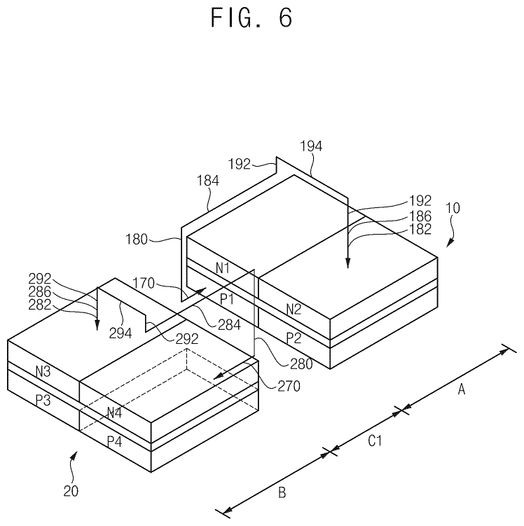

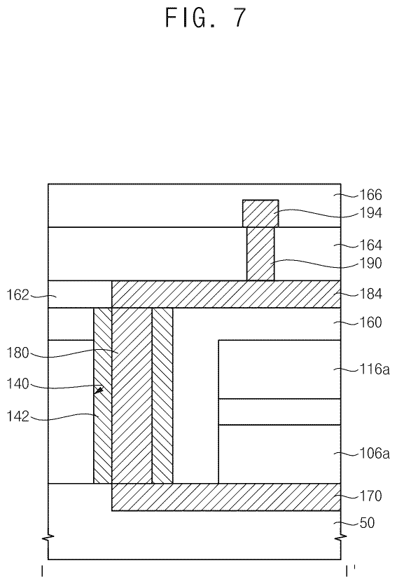

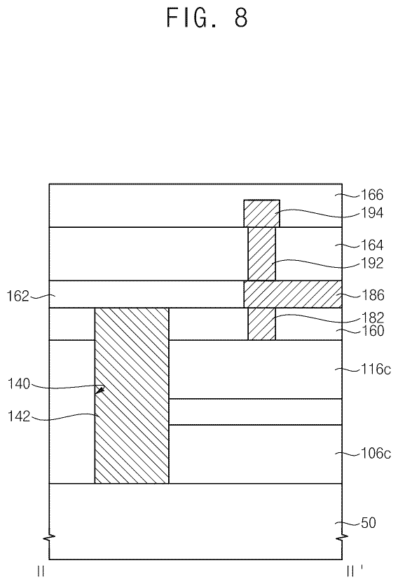

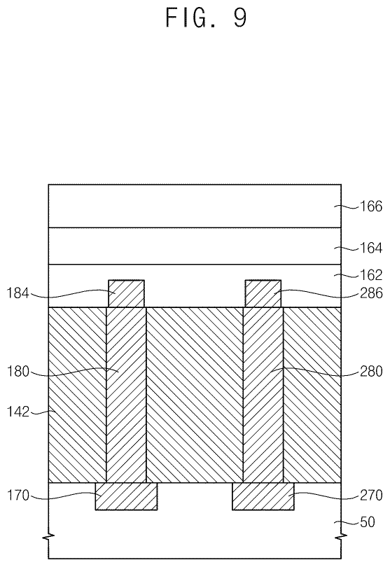

FIG. 1 is a circuit diagram of each of a plurality of cells in a semiconductor device according to example embodiments. FIG. 2A is a schematic plan view of each of a plurality of cells in a semiconductor device according to example embodiments. FIG. 2B is a schematic plan view of each of a plurality of cells in a semiconductor device according to example embodiments. FIG. 3 is a schematic perspective view of a first cell in a semiconductor device according to example embodiments. FIG. 4 is a schematic perspective view of a second cell in a semiconductor device according to example embodiments. FIG. 5 is a schematic plan view illustrating connection wirings in each of a plurality of cells of a semiconductor device according to example embodiments. FIG. 6 is a schematic perspective view illustrating connection wirings in each of a plurality of cells of a semiconductor device according to example embodiments. FIGS. 7 to 9 are schematic cross-sectional views of semiconductor devices according to example embodiments, respectively.

First, with reference to FIG. 1, each of a plurality of cells included in a semiconductor device may be described.

Referring to FIG. 1, a semiconductor device may include a first cell 10 and a second cell 20.

The first cell 10 may include at least two P-type transistors P1 and P2 and at least two N-type transistors N1 and N2. The P-type transistors included in the first cell 10 are referred to as a first P-type transistor P1 and a second P-type transistor P2, respectively. The N-type transistors included in the first cell 10 are referred to as a first N-type transistor N1 and a second N-type transistor N2, respectively.

The first P-type transistor P1 and the second P-type transistor P2 may be connected in series. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The first P-type transistor P1 may include a gate structure and a first source/drain region, and the second P-type transistor P2 may include a gate structure and a second source/drain region. A source/drain region positioned between the first P-type transistor P1 and the second P-type transistor P2 may be commonly used in the first P-type transistor P1 and the second P-type transistor P2, so that the source/drain region positioned between the first P-type transistor P1 and the second P-type transistor P2 may serve as a first common source/drain region.

The first N-type transistor N1 and the second N-type transistor N2 may be connected in series. The first N-type transistor N1 may include a gate structure and a third source/drain region, and the second N-type transistor N2 may include a gate structure and a fourth source/drain region. A source/drain region positioned between the first N-type transistor N1 and the second N-type transistor N2 may be commonly used in the first N-type transistor N1 and the second N-type transistor N2, so that the source/drain region positioned between the first N-type transistor N1 and the second N-type transistor N2 may a second common source/drain region. The first source/drain region of the first P-type transistor PI may be electrically

connected to the second common source/drain region of the first and second N-type transistors N1 and N2.

The second cell 20 may be adjacent to the first cell 10 in the first direction. In addition, the second cell 20 may be spaced apart from the first cell 10 in the first direction.

The second cell 20 may have circuits substantially the same as circuits of the first cell 10. However, positions of connection wirings in the second cell 20 may be different from positions of connection wirings in the first cell 10. The second cell 20 may have a shape in which the first cell 10 is rotated by 180 degrees. The first cell 10 and the second cell 20 may operate independently.

The second cell 20 may include at least two P-type transistors P3 and P4 and at least two N-type transistors N3 and N4. The P-type transistors included in the second cell 20 are referred to as a third P-type transistor P3 and a fourth P-type transistor P4. The N-type transistors included in the second cell 20 are referred to as a third N-type transistor N3 and a fourth N-type transistor N4.

The third P-type transistor P3 may be aligned with the first P-type transistor P1 in the first direction, and the fourth P-type transistor P4 may be aligned with the second P-type transistor P2 in the first direction. The term “aligned,” as may be used herein, is intended to refer to two or more structures or elements each having at least one edge (e.g., sidewall) that is coplanar with one another in the noted direction(s) (e.g., the first direction). The third N-type transistor N3 may be aligned with the first N-type transistor N1 in the first direction, and the fourth N-type transistor N4 may be aligned with the second N-type transistor N2 in the first direction.

The third P-type transistor P3 and the fourth P-type transistor P4 may be connected in series. The third P-type transistor P3 may include a gate structure and a fifth source/drain region, and the fourth P-type transistor P4 may include a gate structure and a sixth source/drain region. A source/drain region positioned between the third P-type transistor P3 and the fourth P-type transistor P4 may be commonly used in the third P-type transistor P3 and the fourth P-type transistor P4, so that the source/drain region positioned between the third P-type transistor P3 and the fourth P-type transistor P4 may serve as a third common source/drain region.

The third N-type transistor N3 and the fourth N-type transistor N4 may be connected in series. The third N-type transistor N3 may include a gate structure and a seventh source/drain region, and the fourth N-type transistor N4 may include a gate structure and an eighth source/drain region. A source/drain region positioned between the third N-type transistor N3 and the fourth N-type transistor N4 may be commonly used in the third N-type transistor N3 and the fourth N-type transistor N4, so that the source/drain region positioned between the third N-type transistor N3 and the fourth N-type transistor N4 may serve as a fourth common source/drain region.

The sixth source/drain region of the fourth P-type transistor N4 may be electrically connected to the fourth common source/drain region of the third and fourth N-type transistors N3 and N4.

Hereinafter, a semiconductor device including the circuits shown in FIG. 1 and implemented on a lower support layer may be described.

Referring to FIGS. 2A and 3 to 9, the first cell 10 and the second cell 20 may be disposed on a lower support layer 50.

The lower support layer 50 may include a first cell region A where transistors included in the first cell 10 are disposed, a second cell region B where transistors included in the second cell 20 are disposed, a first interface region C1 between the first and second cell regions A and B, a second interface region C2 adjacent to (in the first direction) and outside the first cell region A, and a third interface region C3 adjacent to (in the first direction) and outside the second cell region B. The second interface region C2 may face the first interface region C1. The third interface region C3 may face the first interface region C1.

In example embodiments, a third cell 30 may be disposed at a region adjacent to the second interface region C2, and a fourth cell 40 may be disposed at a region adjacent to the third interface region C3. In example embodiments, the third cell 30 may be the same as the first cell 10, and the fourth cell 40 may be the same as the second cell 20.

The first cell region A may have a first width W1 in the first direction. One first cell 10 may be disposed in the first cell region A in the first direction. A plurality of first cells 10 may be repeatedly arranged in the second direction in the first cell region A. An edge of the first cell region A adjacent to the second cell region B is referred to as a first edge, and an edge of the first cell region A facing the first edge is referred to as a second edge.

The second cell region B may have a size the same as a size of the first cell region A. The first cell region A and the second cell region B may have same dimensions in the first and second directions. The second cell region B may have the first width W1 in the first direction. The first and second cell regions A and B may have the same width in the first direction. One second cell 20 may be disposed in the first direction in the second cell region B. A plurality of second cells 20 may be repeatedly arranged in the second direction in the second cell region B. The second cell region B may be spaced apart from the first cell region A in the first direction. An edge of the second cell region B adjacent to the first cell region A is referred to as a third edge, and an edge of the second cell region B facing the third edge is referred to as a fourth edge.

The first interface region C1 may be disposed between the first edge of the first cell region A and the third edge of the second cell region B.

The second interface region C2 may be disposed outside the second edge of the first cell region A, and the third interface region C3 may be disposed outside the fourth edge of the second cell region B.

In example embodiments, each of the first P-type transistor P1, the second P-type transistor P2, the first N-type transistor N1, and the second N-type transistor N2 may include a multi-bridge channel (MBC) field effect transistor or a fin-field effect transistor (fin-FET).

In example embodiments, each of the third P-type transistor P3, the fourth P-type transistor P4, the third N-type transistor N3, and the fourth N-type transistor N4 may include a multi bridge channel-field effect transistor (MBC-FET) or a fin-field effect transistor (fin-FET).

The first P-type transistor P1, the second P-type transistor P2, the first N-type transistor N1 and the second N-type transistor N2 included in the first cell 10, and the third P-type transistor P3, the fourth P-type transistor P4, the third N-type transistor N3, and the fourth N-type transistor N4 included in the second cell 20 may be transistors having the same structure. For example, the transistors included in the first and second cells 10 and 20 may be the multi bridge channel-field effect transistors. However, the structure of the transistors may not be limited to thereto.

First, the transistors included in the first cell 10 may be described.

One conductivity type transistors among the N-type transistors N1 and N2 or P-type transistors P1 and P2 included in the first cell 10 may be disposed at a lower level region, and the remaining conductivity type transistors may be disposed at an upper level region.

In example embodiments, the first and second N-type transistors N1 and N2 may be disposed over the first and second P-type transistors P1 and P2. The first and second P-type transistors P1 and P2 may be disposed at the lower level region, and the first and second N-type transistors N1 and N2 may be disposed at the upper level region.

In the following description, the P-type transistors P1 and P2 disposed at the lower level region are described, but may not be limited thereto. In some example embodiments, the first and second N-type transistors N1 and N2 may be disposed at the lower level region, and the first and second P-type transistors P1 and P2 may be disposed at the upper level region.

In example embodiments, the first N-type transistor N1 may be spaced apart from the first P-type transistor P1 in the vertical direction, and the second N-type transistor N1 may be spaced apart from the second P-type transistor P2 in the vertical direction. The first P-type transistor P1 and the first N-type transistor N1 may be aligned to each other in the vertical direction. The second P-type transistor P2 and the second N-type transistor N2 may be aligned to each other in the vertical direction.

In example embodiments, as shown in FIG. 3, each of the first and second P-type transistors P1 and P2 may include a first nanosheet structure 100, a first gate structure 102, and a first semiconductor structure 104. The first gate structure 102 may extend in the first direction while passing through (i.e., extending in) the first nanosheet structure 100. A plurality of first gate structures 102 spaced apart from each other in the vertical direction may pass through the first nanosheet structure 100.

The first semiconductor structure 104 may be disposed on both (i.e., opposing) sides in the second direction of the first gate structure 102 and the first nanosheet structure 100. The first semiconductor structure 104 may be doped with P-type impurities to form the first source/drain region 106a of the first P-type transistor P1 and the second source/drain region 106b of the second P-type transistor P2. The first semiconductor structure 104 disposed between the first gate structures 102 in the second direction may serve as the first common source/drain region 106c of the first and second P-type transistors P1 and P2. Accordingly, the first and second P-type transistors P1 and P2 may be connected in series in the second direction.

Each of the first and second N-type transistors N1 and N2 may include a second nanosheet structure 110, a second gate structure 112, and a second semiconductor structure 114. The second gate structure 112 may extend in the first direction while passing through the second nanosheet structure 110. The second semiconductor structure 114 may be disposed on both (i.e., opposing) sides in the second direction of the second gate structure 112 and the second nanosheet structure 110. The second semiconductor structure 114 may be doped with N-type impurities to form the third source/drain region 116a of the first N-type transistor N1 and the fourth source/drain region 116b of the second N-type transistor N2. The second semiconductor structure 114 disposed between the second gate structures 112 may serve as the second common source/drain region 116c of the first and second N-type transistors N1 and N2. Accordingly, the first and second N-type transistors N1 and N2 may be connected in series in the second direction.

Each of the first gate structure 102 and the second gate structure 112 may include a first end E1 and a second end E2 in the first direction. Here, the first end E1 may be an end adjacent to the second cell region B, and the second end E2 may be an end opposite to the first end E1 in the first direction.

In example embodiments, each of the first and second ends E1 and E1 of the first gate structure 102 may protrude (i.e., extend outwardly) from a sidewall in the first direction of the first nanosheet structure 100. Each of the first and second ends E1 and E2 of the second gate structure 112 may protrude from a sidewall in the first direction of the second nanosheet structure 110.

In example embodiments, the first ends E1 of the first and second gate structures 102 and 112 may be aligned to each other in the vertical direction. The second ends E2 of the first and second gate structures 102 and 112 may be aligned to each other in the vertical direction. The first ends E1 of the first gate structures 102 may be aligned to each other in the second direction, and second ends E2 of the first gate structures 102 may be aligned to each other in the second direction. The first ends E1 of the second gate structures 112 may be aligned to each other in the second direction, and second ends E2 of the second gate structures 112 may be aligned to each other in the second direction.

In example embodiments, in a plan view, the first ends E1 of the first gate structure 102 and the second gate structure 112 may contact the first edge of the first cell region A. The second ends E2 of the first gate structure 102 and the second gate structure 112 may contact the second edge of the first cell region A. In the plan view, the first end E1 of each of the first gate structure 102 and the second gate structure 112 may contact an edge of the first interface region C1 adjacent to the first cell region A. The second end E2 of each of the first gate structure 102 and the second gate structure 112 may contact an edge of the second interface region C2 adjacent to the first cell region A.

The first and second edges of the first cell region A may be defined by the first and second ends E1 and E2 of the first and second gate structures 102 and 112, respectively. The transistors of the second cell 20 may be described.

The second cell 20 may include elements the same as elements included in the first cell 10. However, the second cell 20 may have an arrangement of the elements different from an arrangement of the elements included in the first cell 10. The second cell 20 may have a shape in which the first cell 10a is rotated by 180 degrees.

Transistors disposed at the lower level region in the second cell 20 may have a conductivity type the same as the conductivity of the transistors disposed at the lower level region in the first cell 10. Transistors disposed at the upper level region in the second cell 20 may have a conductivity type the same as the conductivity of the transistors disposed at the upper level region in the first cell 10.

In example embodiments, the third and fourth N-type transistors N3 and N4 may be disposed over the third and fourth P-type transistors P3 and P4. The third and fourth P-type transistors P3 and P4 may be disposed at the lower level region, and the third and fourth N-type transistors N3 and N4 may be disposed at the upper level region. In this case, the first to fourth P-type transistors P1, P2, P3 and P4 may be lower level transistors, and the first to fourth N-type transistors N1, N2, N3 and N4 may be upper level transistors.

In example embodiments, the third N-type transistor N3 may be spaced apart from the third P-type transistor P3 in the vertical direction, and the fourth N-type transistor N3 may be spaced apart from the fourth P-type transistor P4 in the vertical direction. The third P-type transistor P3 and the third N-type transistor N3 may be aligned to each other in the vertical direction. The fourth P-type transistor P4 and the fourth N-type transistor N4 may be aligned to each other in the vertical direction.

In example embodiments, the first and third P-type transistors P1 and P3 may be aligned to each other in the first direction. The second and fourth P-type transistors P2 and P4 may be aligned to each other in the first direction. The first and third N-type transistors N1 and N3 may be aligned to each other in the first direction. The second and fourth N-type transistors N2 and N4 may be aligned to each other in the first direction.

As shown in FIG. 4, each of the third and fourth P-type transistors P3 and P4 may include a third nanosheet structure 120, a third gate structure 122, and a third semiconductor structure 124. The third gate structure 122 may extend in the first direction while passing through the third nanosheet structure 120. A plurality of third gate structures 122 spaced apart from each other in the vertical direction may pass through the third nanosheet structure 120.

The third semiconductor structure 124 may be disposed on both sides in the second direction of the third gate structure 122 and the third nanosheet structure 120. The third semiconductor structure 124 may be doped with P-type impurities to form the fifth source/drain region 126a of the third P-type transistor P3 and the sixth source/drain region 126b of the fourth P-type transistor P4. The third semiconductor structure 124 disposed between the third gate structures 122 in the second direction may serve as the third common source/drain region 126c of the third and fourth P-type transistors P3 and P4. Accordingly, the third and fourth P-type transistors P3 and P4 may be connected in series in the second direction.

Each of the third and fourth N-type transistors N3 and N4 may include a fourth nanosheet structure 130, a fourth gate structure 132, and a fourth semiconductor structure 134. The fourth gate structure 132 may extend in the first direction while passing through the fourth nanosheet structure 130. The fourth semiconductor structure 134 may be disposed on both sides in the second direction of the fourth gate structure 132 and the fourth nanosheet structure 130. The fourth semiconductor structure 134 may be doped with N-type impurities to form the seventh source/drain region 136a of the third N-type transistor N3 and the eighth source/drain region 136b of the fourth N-type transistor N4. The fourth semiconductor structure 134 disposed between the fourth gate structures 132 in the second direction may serve as the fourth common source/drain region 136c of the third and fourth N-type transistors N3 and N4. Accordingly, the third and fourth N-type transistors N3 and N4 may be connected in series in the second direction.

Each of the third gate structure 122 and the fourth gate structure 132 may include a third end E3 and a fourth end E4 in the first direction. Herein, the third end E3 may be an end adjacent to the first cell region A, and the fourth end E4 may be an end opposite to the third end E3.

In example embodiments, each of the third and fourth ends E3 and E4 of the third gate structure 122 may protrude (i.e., extend outwardly) from a sidewall in the first direction of the third nanosheet structure 120. Each of the third and fourth ends E3 and E4 of the fourth gate structure 132 may protrude from a sidewall in the first direction of the fourth nanosheet structure 130.

In example embodiments, the third ends E3 of the third and fourth gate structures 122 and 132 may be aligned to each other in the vertical direction. The fourth ends E4 of the third and fourth gate structures 122 and 132 may be aligned to each other in the vertical direction. The third ends E3 of the third gate structures 122 may be aligned to each other in the second direction, and the fourth ends E4 of the third gate structures 122 may be aligned to each other in the second direction. The third ends E3 of the fourth gate structures 132 may be aligned to each other in the second direction, and the fourth ends E4 of the fourth gate structures 132 may be aligned to each other in the second direction.

In example embodiments, in the plan view, the third ends E3 of the third gate structure 122 and the fourth gate structure 132 may contact the third edge of the second cell region B. The fourth ends E4 of the third gate structure 122 and the fourth gate structure 132 may contact the fourth edge of the second cell region B. In the plan view, the third ends E3 of the third gate structure 122 and the fourth gate structure 132 may contact an edge of the first interface region C1 adjacent to the second cell region B. The fourth ends E4 of the third gate structure 122 and the fourth gate structure 132 may contact an edge of the third interface region C3 adjacent to the second cell region B.

The third edge of the second cell region B may be defined by the third ends E3 of the third and fourth gate structures 122 and 132. The fourth edge of the second cell region B may be defined by the fourth ends E4 of the third and fourth gate structures 122 and 132.

In example embodiments, the first gate structure 102 and the third gate structure 122 may be aligned to each other in the first direction. In example embodiments, the second gate structure 112 and the fourth gate structure 132 may be aligned to each other in the first direction.

The first interface region C1 may correspond to a region between the first ends E1 of the first and second gate structures 102 and 112 and the third ends E3 of the third and fourth gate structures 122 and 132.

The second interface region C2 may correspond to outsides of the second ends E2 of the first and second gate structures 102 and 112. The third interface region C3 may correspond to outsides of the fourth ends E4 of the third and fourth gate structures 122 and 132.

In example embodiments, the second and third interface regions C2 and C3 may have the same width in the first direction.

The first interface region C1 may have a second width W2 in the first direction, and each of the second and third interface regions C2 and C3 has a third width W3 in the first direction. The second width W2 and the third width W3 may be different from each other. In example embodiments, the second width W2 may be greater than the third width W3.

A first insulation pattern structure 142 may be disposed on the first interface region C1.

In example embodiments, a first trench 140 may be disposed in the first interface region C1. The first trench 140 may be formed by a gate cutting process for forming the first and third gate structures 102 and 122 and the second and fourth gate structures 112 and 132. The first trench 140 may extend in the second direction. The first insulation pattern structure 142 may fill the first trench 140. The term “fill” (or “filling,” “filled,” or like terms), as may be used herein, is intended to refer broadly to either completely filling a defined space (e.g., the first trench 140) or partially filling the defined space; that is, the defined space need not be entirely filled but may, for example, be partially filled or have voids or other spaces throughout. The first ends E1 of the first and second gate structures 102 and 112 and the third ends E3 of the third and fourth gate structures 122 and 132 may be exposed by sidewalls of the first trench 140. The term “exposed” (or “exposes,” or like terms) may be used herein to describe relationships between elements and/or with reference to intermediate processes in fabricating an integrated circuit device, but may not require exposure of a particular element in the completed device. Likewise, the term “not exposed” may be used to described relationships between elements and/or with reference to intermediate processes in fabricating an integrated circuit device, but may not require a particular element to be unexposed in the completed device. Accordingly, a first sidewall of the first insulation pattern structure 142 may contact the first ends E1 of the first and second gate structures 102 and 112, and a second sidewall of the first insulation pattern structure 142 may contact the third ends E3 of the third and fourth gate structures 122 and 132.

The first insulation pattern structure 142 may extend in the vertical direction to a portion below bottoms of the first and third gate structures 102 and 122 disposed at a lowermost portion from a portion above upper surfaces of the second and fourth gate structures 112 and 132 disposed at an uppermost portion. The first insulation pattern structure 142 may extend in the second direction. An uppermost surface of the first insulation pattern structure 142 may be higher than the upper surfaces of the second and fourth gate structures 112 and 132 disposed at the uppermost portion, relative to an upper surface of the lower support layer 50 as a reference layer. A lowermost surface of the first insulation pattern structure 142 may be lower than the bottoms of the first and third gate structures 102 and 122 disposed at the lowermost portion, relative to an upper surface of the lower support layer 50.

A second insulation pattern structure 146 may be disposed on the second interface region C2, and a third insulation pattern structure 150 may be disposed on the third interface region C3.

In example embodiments, a second trench 144 may be disposed in the second interface region C2. The second trench 144 may be formed by a gate cutting process for forming the first and second gate structures 102 and 112. A sidewall of the second trench 144 may expose the second ends E2 of the first and second gate structures 102 and 112, and the second trench 144 may extend in the second direction. A third trench 148 may be disposed in the third interface region C3. The third trench 148 may be formed by a gate cutting process for forming the third and fourth gate structures 122 and 132. A sidewall of the third trench 148 may expose the fourth ends E4 of the third and fourth gate structures 122 and 132, and the third trench 148 may extend in the second direction.

The second insulation pattern structure 146 may at least partially fill the second trench 144. A first sidewall of the second insulation pattern structure 146 may contact the second ends E2 of the first and second gate structures 102 and 112.

The second insulation pattern structure 146 may extend in the vertical direction to a portion below the bottom of the first gate structures 102 disposed at the lowermost portion from a portion above the upper surface of the second gate structure 112 disposed at the uppermost portion. The second insulation pattern structure 146 may extend in the second direction. An uppermost surface of the second insulation pattern structure 146 may be higher than the uppermost surface of the second gate structure 112 disposed at the uppermost portion, relative to an upper surface of the lower support layer 50 as a reference layer. A lowermost surface of the second insulation pattern structure 146 may be lower than the bottom of the first gate structure 102 disposed at the lowermost portion, relative to an upper surface of the lower support layer 50.

The third insulation pattern structure 150 may at least partially fill the third trench 148. A first sidewall of the third insulation pattern structure 150 may contact the fourth ends E4 of the third and fourth gate structures 122 and 132.

The third insulation pattern structure 150 may extend in the vertical direction from a portion above an upper surface of the fourth gate structure 132 disposed at the uppermost portion to a portion below a bottom of the third gate structure 122 disposed at the lowermost portion. The third insulation pattern structure 150 may extend in the second direction. An uppermost surface of the third insulation pattern structure 150 may be higher than the upper surface of the fourth gate structure 132 disposed at the uppermost portion, relative to an upper surface of the lower support layer 50 as a reference layer. A lowermost surface of the third insulation pattern structure 150 may be lower than the bottom of the third gate structure 122 disposed at the lowermost portion, relative to an upper surface of the lower support layer 50.

In example embodiments, the first to third insulation pattern structures 142, 146, and 150 may include the same insulation material. For example, the first to third insulation pattern structures 142, 146, and 150 may include silicon nitride.

In example embodiments, the first insulation pattern structure 142 may have the second width W2 in the first direction. Each of the second and third insulation pattern structures 146 and 150 may have the third width W3 in the first direction.

In example embodiments, the second width W2 may be greater than a diameter of a through plug (hereinafter, a maximum through plug) having a greatest diameter and greatest depth among through plugs passing through the first insulation pattern structure 142 on the first interface region C1. Since only one maximum through plug may be disposed within the first insulation pattern structure 142 in the first direction, the second width W2 may be greater than the diameter of the maximum through plug. For example, the second width W2 may be 110% to 300% of the diameter of the maximum through plug. When the second width W2 is less than 110% of the diameter of the maximum through plug, it may not be easy to form the maximum through plug within the first interface region C1. Since only one maximum through plug is formed within the first interface region C1 having the second width W2, the second width W2 may not need to be more than three times the diameter of the maximum through plug. In example embodiments, the second width W2 may have a width of about 1.2 times to about 2 times the diameter of the maximum through plug.

A first insulating interlayer 160 covering the transistors included in the first cell 10 and the transistors included in the second cell 20 may be disposed on the first cell region A and the second cell region B. The term “covering” (or “cover” or “covers,” or like terms), as may be used herein, is intended to broadly refer to a material, layer or structure being on or over another material, layer or structure, but does not require the material, layer or structure to entirely cover the other material, layer or structure. A second insulating interlayer 162, a third insulating interlayer 164 and an upper insulating interlayer 166 may be sequentially disposed on the first insulating interlayer 160 and the first insulation pattern structure 142.

Hereinafter, connections of the first and second P-type transistors P1 and P2 and the first and second N-type transistors N1 and N2 in the first cell 10 may be described.

Hereinafter, among sidewalls in the second direction of each of gate structures, a sidewall adjacent to the edge in the second direction of each of cells is referred to as a first sidewall, and a sidewall opposite to the first sidewall is referred to as a second sidewall.

Referring to FIGS. 2A to 9, in the first P-type transistor P1, a first connection wiring 170 may contact the first source/drain region 106a adjacent to the first sidewall of the first gate structure 102. The first connection wiring 170 may horizontally extend in the first direction to inside of the first interface region C1 from the first source/drain region 106a. The fifth end of the first connection wiring 170 may be positioned in the first cell region A, and the sixth end E6 of the first connection wiring 170 may be positioned in the first interface region C1.

The first connection wiring 170 may contact a surface of the first semiconductor structure 104 serving as the first source/drain region 106a. In example embodiments, the first connection wiring 170 may contact a bottom of the first semiconductor structure 104 serving as the first source/drain region 106a. Alternatively, the first connection wiring 170 may contact a sidewall of the first semiconductor structure 104 serving as the first source/drain region 106a.

In example embodiments, the sixth end E6 of the first connection wiring 170 may be between a center of the first insulation pattern structure 142 in the first direction and the third edge of the second cell region B. In example embodiments, a portion of the first connection wiring 170 may overlap a first through via 180. The term “overlap” (or “overlapping,” or like terms), as may be used herein, is intended to broadly refer to a first element that intersects with at least a portion of a second element in the vertical direction, but does not require that the first and second elements be completely aligned with one another in a horizontal plane (i.e., in the first direction and/or the second direction).

The first through via 180 may pass through the first insulation pattern structure 142, and may extend into an upper surface of the first connection wiring 170. In example embodiments, an upper surface of the first through via 180 may be coplanar with an upper surface of the first insulation pattern structure 142. In example embodiments, the upper surface of the first through via 180 may be coplanar with an upper surface of the first insulating interlayer 160.

The first through via 180 may be a maximum through plug passing through the first insulation pattern structure 142.

In example embodiments, the upper surface of the first through via 180 may be higher than upper surfaces of uppermost gate structures in the first and second N-type transistors N1 and N2, relative to the upper surface of the lower support layer 50 as a reference layer. For example, the upper surface of the first through via 180 may be higher than uppermost portions of the first and second N-type transistors N1 and N2, relative to the upper surface of the lower support layer 50.

A bottom of the first through via 180 may contact the upper surface of the first connection wiring 170. In example embodiments, the bottom of the first through via 180 may be lower than bottoms of lowermost gate structures in the first and second P-type transistors P1 and P2, relative to the upper surface of the lower support layer 50.

The first through via 180 may be disposed on a first straight line that passes a center in the first direction of the first interface region Cl and extends in the second direction. At least a portion of the bottom of the first through via 180 may contact a portion corresponding to the first straight line. Accordingly, in a cross-sectional view taken along a line extending in the second direction and passing the center of the first interface region C1 in the first direction, the first through via 180 may be shown.

In example embodiments, the first through via 180 may be disposed on the center of the first interface region C1 in the first direction. The first through via 180 may be disposed on the center of the first insulation pattern structure 142 in the first direction. The first through via 180 may be disposed on a center portion in the first direction of a region between the first gate structure 102 and the third gate structure 122. The first through via 180 may be disposed on the center portion in the first direction of a region between the second gate structure 112 and the fourth gate structure 132.

A first contact plug 182 may be on the second semiconductor structure 114 corresponding to the second common source/drain region 116c of the first N-type transistor and the second N-type transistor. The first contact plug 182 may be electrically connected to the second common source/drain region 116c.

The first contact plug 182 may pass through the first insulating interlayer 160, and may contact an upper surface of the second semiconductor structure 114. In example embodiments, an upper surface of the first contact plug 182 may be coplanar with the upper surface of the first insulating interlayer 160. The upper surface of the first contact plug 182 and an upper surface of the first through via 180 may be coplanar with each other.

A second connection wiring 184 may contact the upper surface of the first through via 180. A third connection wiring 186 may contact the upper surface of the first contact plug 182. The second and third connection wirings 184 and 186 may pass through the second insulating interlayer 162.

The second connection wiring 184 may extend in the first direction from the upper surface of the first through via 180 in the first interface region C1 to inside of the first cell region A. The seventh end E7 of the second connection wiring 184 may be disposed on the first interface region C1, and the eighth end E8 of the second connection wiring 184 may be disposed on the first cell region A.

The third connection wiring 186 may be disposed inside of the first cell region A. An upper surface of the second connection wiring 184 may be coplanar with an upper surface of the third connection wiring 186.

In example embodiments, at least a portion of the second connection wiring 184 may face the third connection wiring 186 in a horizontal direction.

A first upper via 190 may contact the upper surface of the second connection wiring 184. A second upper via 192 may contact the upper surface of the third connection wiring 186. The first and second upper vias 190 and 192 may pass through (i.e., extend in) the third insulating interlayer 164 in the vertical direction.

A fourth connection wiring 194 electrically connecting the first upper via 190 and the second upper via 192 may be formed on the third insulating interlayer 164, the first upper via 190 and the second upper via 192. The fourth connection wiring 194 may have a line shape extending in the second direction.

Hereinafter, connections between the third and fourth P-type transistors P3 and P4 and the third and fourth N-type transistors N3 and N4 in the second cell 20 are described. A connection structure of the second cell 20 may be the same as a connection structure of the first cell 10 rotated by 180 degrees.

A fifth connection wiring 270 may contact the fourth p-type transistor P4, and a sixth source/drain region 126b adjacent to a first sidewall of the third gate structure 122. The fifth connection wiring 270 may extend horizontally in the first direction from the sixth source/drain region 126b into the inside of the first interface region C1. A ninth end E9 of the fifth connection wiring 270 may be disposed on the second cell region B, and a tenth end E10 of the fifth connection wiring 270 may be disposed on the first interface region C1. In example embodiments, the fifth connection wiring 270 may contact a bottom of the third semiconductor structure 124 serving as the sixth source/drain region 126b. Alternatively, the fifth connection wiring 270 may contact a sidewall of the third semiconductor structure 124 serving as the sixth source/drain region 126b.

In example embodiments, the tenth end E10 of the fifth connection wiring 270 may be disposed between the center of the first insulation pattern structure 142 in the first direction and a first edge of the first cell region A. In example embodiments, a portion of the fifth connection wiring 270 may overlap a second through via 280.

The second through via 280 may extend in the vertical direction through the first insulation pattern structure 142 to an upper surface of the fifth connection wiring 270. In example embodiments, an upper surface of the second through via 280 may be coplanar with the upper surface of the first insulation pattern structure 142. In example embodiments, the upper surface of the second through via 280 may be coplanar with the upper surface of the first insulating interlayer 160.

The second through via 280 may be a maximum through plug passing through the first insulation pattern structure 142.

In example embodiments, the second through via 280 may have a shape substantially the same as a shape of the first through via 180. For example, the second through via 280 may have a diameter substantially the same as a diameter of the first through via 180. The second through via 280 may have a height substantially the same as a height of the first through via 180.

In example embodiments, the upper surface of the second through via 280 may be higher than upper surfaces of uppermost gate structures of the third and fourth N-type transistors N3 and N4, relative to the upper surface of the lower support layer 50 as a reference layer. For example, the upper surface of the second through via 280 may be higher than uppermost portions of the third and fourth N-type transistors N3 and N4, relative to the upper surface of the lower support layer 50.

A bottom of the second through via 280 may contact the upper surface of the fifth connection wiring 270. In example embodiments, the bottom of the second through via 280 may be lower than bottoms of lowermost gate structures of the third and fourth P-type transistors P3 and P4, relative to the upper surface of the lower support layer 50.

The second through via 280 may be disposed on the first straight line that passes the center in the first direction of the first interface region C1 and extends in the second direction. At least a portion of the bottom of the second through via 280 may contact a portion corresponding to the first straight line.

Accordingly, in a cross-sectional view taken along a line extending in the second direction and passing through the center of the first interface region C1 in the first direction, the second through via 280 may be shown. In the cross-sectional view taken along the line extending in the second direction and passing through the center of the first interface region C1 in the first direction, the first through via 180 in the first cell 10 and the second through via 280 in the second cell 20 may be shown together.

In example embodiments, the first and second through vias 180 and 280 may be on the first straight line, and may be aligned in the second direction. Alternatively, as shown in FIG. 2B, the first and second through vias 180 and 280 may be on the first straight line, and may not be aligned in the second direction.

In example embodiments, the second through via 280 may be disposed on the center of the first interface region C1 in the first direction. The second through via 280 may be disposed on the center of the first insulation pattern structure 142 in the first direction. The second through via 280 may be disposed on a center portion between the first gate structure 102 and the third gate structure 122 in the first direction. The second through via 280 may be disposed on a center portion between the second gate structure 112 and the fourth gate structure 132 in the first direction.

In example embodiments, the first through via 180 and the second through via 280 may be aligned to each other in the second direction.

A second contact plug 282 may be formed on the fourth semiconductor structure 134 corresponding to the fourth common source/drain region 136c of the third and fourth n-type transistors N3 and N4. The second contact plug 282 may be electrically connected to the fourth common source/drain region 136c.

The second contact plug 282 may pass through the first insulating interlayer 160 and may contact the upper surface of the fourth semiconductor structure 134. An upper surface of the second contact plug 282 may be coplanar with the upper surface of the first insulating interlayer 160. Accordingly, the upper surface of the second contact plug 282 and the upper surface of the second through via 280 may be coplanar with each other.

A sixth connection wiring 284 may contact the upper surface of the second through via 280. A seventh connection wiring 286 may contact the upper surface of the second contact plug 282. The sixth and seventh connection wirings 284 and 286 may pass through the second insulating interlayer 162.

The sixth connection wiring 284 may extend in the first direction from the upper surface of the second through via 280 in the first interface region C1 to inside of the second cell region B. An eleventh end E11 of the sixth connection wiring 284 may be disposed on the first interface region C1, and a twelfth end E12 of the sixth connection wiring 284 may be disposed in the second cell region B.

The seventh connection wiring 286 may be disposed inside the second cell region B. An upper surface of the seventh connection wiring 286 may be coplanar with an upper surface of the sixth connection wiring 284.

In example embodiments, at least a portion of the sixth connection wiring 284 may face the seventh connection wiring 286 in the horizontal direction.

A third upper via 290 may contact the upper surface of the sixth connection wiring 284. A fourth upper via 292 may contact the upper surface of the seventh connection wiring 286. The third and fourth upper vias 290 and 292 may pass through the third insulating interlayer 164.

An eighth connection wiring 294 electrically connected to the third upper via 290 and the fourth upper via 292 may be formed on the third insulating interlayer 164, the third upper via 290, and the fourth upper via 292. The eighth connection wiring 294 may have a line shape extending in the second direction.

Wirings being electrically connected to the first source/drain region of the first P-type transistor, the second common source/drain region of the second N-type transistor and the first through via 180 in the first cell 10 may be a first wiring group. For example, the first wiring group may include the first to fourth connection wirings 170, 184, 186, and 194, the first contact plug 182, and the first and second upper vias 190 and 192.

Wirings being electrically connected to the sixth source/drain region of the fourth P-type transistor and the fourth common source/drain region of the fourth N-type transistor and the second through via 280 in the second cell 20 may be a second wiring group. For example, the second wiring group may include the fifth to eighth connection wirings 270, 284, 286, 294, the second contact plug 282, and the third and fourth upper vias 290 and 292.

The second wiring group and the second through via 280 may have a shape as the same as a shape the first wiring group and the first through via 180 rotated by 180 degrees.

The upper insulating interlayer 166 may cover the third insulating interlayer 164 and the fourth and eighth connection wirings 194 and 294.

The lower support layer 50 may cover lower portions of the first and fifth connection wirings 170 and 270 and transistors P1, P2, P3, and P4 on a first-floor (hereinafter, first-floor transistors). The lower support layer 50 may include an insulation material.

As described above, the first cell 10 and the second cell 20 may have substantially the same circuits. The second cell 20 may be arranged to have a shape in which the first cell 10 is rotated by 180 degrees.

The first through via 180 of the first cell 10 and the second through via 280 of the second cell 20 may be disposed on the first interface region C1 between the first cell region A and the second cell region B. The first through via 180 may have a height higher than a height of a stacked structure including transistors vertically stacked in the first cell 10, relative to the upper surface of the lower support layer 50 as a reference layer. The second through via 280 may have a height higher than a height of a stacked structure including transistors stacked vertically in the second cell 20, relative to the upper surface of the lower support layer 50.

The first through via 180 and the second through via 280 may be disposed on the center of the first interface region C1 in the first direction. The first through via 180 and the second through via 280, which are elements of different first and second cells 10 and 20, may be disposed on the first interface region C1 together, so that a second width W2 of the first interface region C1 required to form the first and second through vias 180 and 280 may be decreased. Additionally, the through vias may not be disposed on the second and third interface regions C2 and C3 and the first and second cell regions A and B. Accordingly, the third width W3 of each of the second and third interface regions C2 and C3 may be less than the second width W2. Accordingly, a horizontal area of the semiconductor device including the first cell 10 and the second cell 20 may be decreased.

The first cell 10 and the second cell 20 as described above may be used as a portion of various circuits in which source/drain regions of the transistors of different conductivity types are connected to each other. For example, the first and second cells 10 and 20 may be used as portions of an AOI (AND-OR-Invert) circuit or AO (AND-OR) circuit.

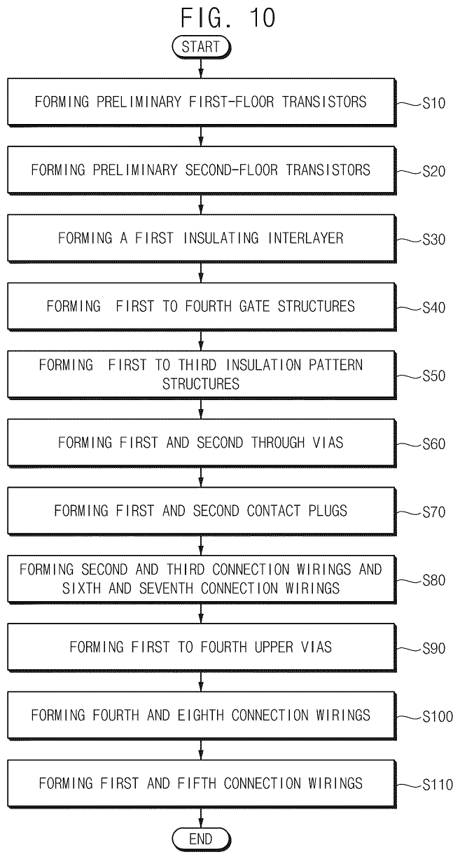

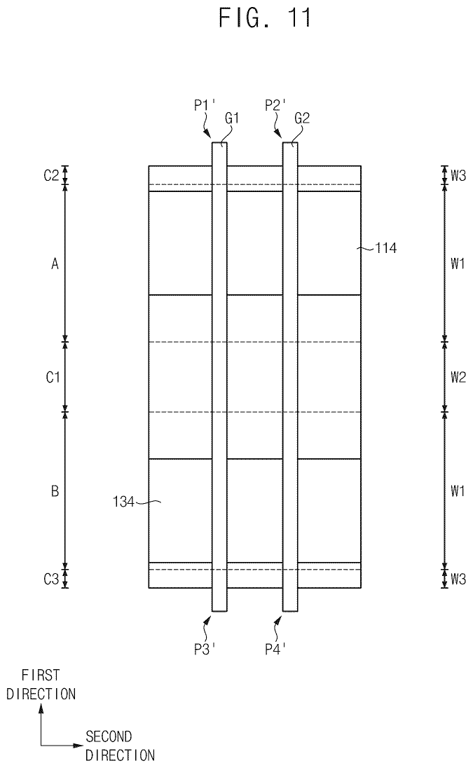

FIG. 10 is a flowchart illustrating a method of manufacturing a semiconductor device according to example embodiments. FIGS. 11 to 19 are schematic plan views illustrating intermediate processes in a method of manufacturing a semiconductor device according to example embodiments.

Referring to FIGS. 10 and 11, preliminary first-floor transistors P1′, P2′, P3′, and P4′ may be formed on a substrate. (S10)

The substrate may include a first cell region A where transistors included in a first cell are disposed, a second cell region B where transistors included in a second cell are disposed, a first interface region C1 between the first and second cell regions A and B, a second interface region C2 positioned outside and adjacent (in the first direction) the first cell region A, and a third interface region C3 positioned outside and adjacent (in the first direction) the second cell region B.

The first and second cell regions A and B may have a first width W1 in the first direction. The first interface region C1 may have a second width W2 in the first direction, and each of the second and third interface regions C2 and C3 may have a third width W3 in the first direction. The second width W2 and the third width W3 may be different from each other. In example embodiments, the second width W2 may be greater than the third width W3. In example embodiments, the first width W1 may be greater than the second width W2.

In example embodiments, a preliminary first P-type transistor P1′ and a preliminary second P-type transistor P2′ may be formed on the first cell region A of the substrate. Additionally, a preliminary third P-type transistor P3′ and a preliminary fourth P-type transistor P4′ may be formed on the second cell region B of the substrate.

The first preliminary P-type transistor P1′ and the third preliminary P-type transistor P3′ may include one first preliminary gate structure G1 extending in the first direction. The first preliminary gate structure G1 may be formed on the first cell region A, the second cell region B, and the first to third interface regions C1, C2, and C3.

The second preliminary P-type transistor P2′ and the fourth preliminary P-type transistor P4′ may include one second preliminary gate structure G2 extending in the first direction. The second preliminary gate structure G2 may be formed on the first cell region A, the second cell region B, and the first to third interface regions C1, C2, and C3.

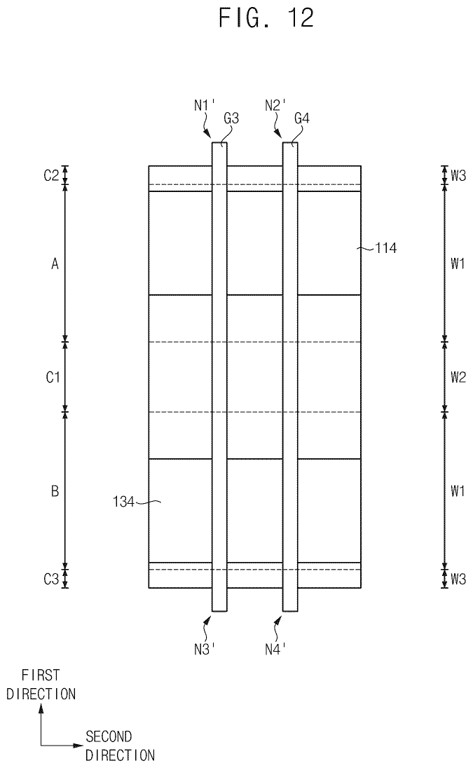

Referring to FIGS. 10 and 12, preliminary second-floor transistors N1′, N2′, N3′, and N4′ may be formed over the preliminary first-floor transistors P1′, P2′, P3′, and P4′. (S20) The preliminary second-floor transistors N1′, N2′, N3′, and N4′ may be spaced apart from the preliminary first-floor transistors P1′, P2′, P3′, and P4′ in the vertical direction. The preliminary second-floor transistors N1′, N2′, N3′, and N4′ and the preliminary first-floor transistors P1′, P2′, P3′, and P4′ may overlap to each other in the vertical direction.

In example embodiments, a preliminary first N-type transistor N1′ and a preliminary second N-type transistor N2′ may be formed on the first cell region A of the substrate. Additionally, a preliminary third N-type transistor N3′ and a preliminary fourth N-type transistor N4′ may be formed on the second cell region B of the substrate.

The first preliminary N-type transistor N1′ and the third preliminary N-type transistor N3′ may include one third preliminary gate structure G3 extending in the first direction. The third preliminary gate structure G3 may be formed on the first cell region A, the second cell region B, and the first to third interface regions C1, C2, and C3.

The preliminary second N-type transistor N2′ and the preliminary fourth N-type transistor N4′ may include one fourth preliminary gate structure G4 extending in the first direction. The fourth preliminary gate structure G4 may be formed on the first cell region A, the second cell region B, and the first to third interface regions C1, C2, and C3.

The preliminary first N-type transistor N1′ may be formed over the preliminary first P-type transistor P1′. The preliminary second N-type transistor N2′ may be formed over the preliminary second P-type transistor P2′. The preliminary third N-type transistor N3′ may be formed over the preliminary third P-type transistor P3′. The preliminary fourth N-type transistor N4′ may be formed over the preliminary fourth P-type transistor P4′.

Thereafter, a first insulating interlayer may be formed on the substrate to cover the preliminary first-floor transistors P1′, P2′, P3′, and P4′ and the preliminary second-floor transistors N1′, N2′, N3′, and N4′. (S30)

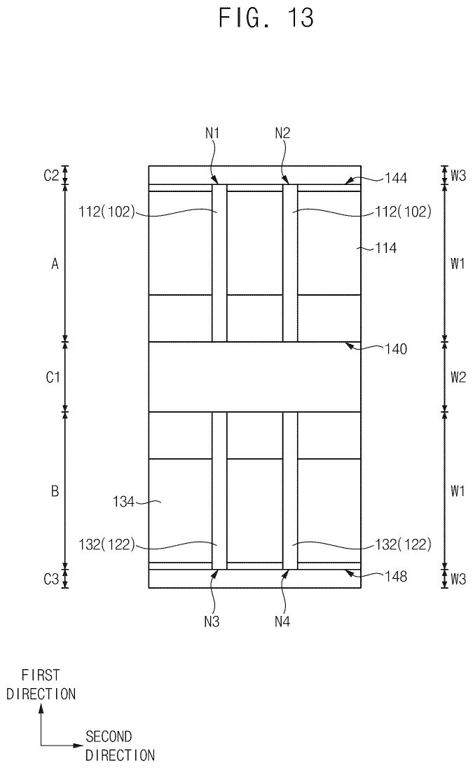

Referring to FIGS. 10 and 13, the first insulating interlayer and the first to fourth preliminary gate structures G1, G2, G3, G4 on the first interface region C1, the second interface region C2, and the third interface region C3 may be etched to form the first to fourth gate structures 102, 112, 122, and 132. (S40) The etching process may be a gate cutting process.

The first preliminary gate structure G1 and the second preliminary gate structure G2 may be cut by the etching process to form the first gate structure 102 and the third gate structure 122, respectively. Additionally, the third preliminary gate structure G3 and the fourth preliminary gate structure G4 may be cut to form the second gate structure 112 and the fourth gate structure 132, respectively.

The first gate structure 102 may serve as a gate of the first and second P-type transistors P1 and P2, and the second gate structure 112 may serve as a gate of the first and second N-type transistors N1 and N2. The third gate structure 122 may serve as a gate of the third and fourth P-type transistors P3 and P4, and the fourth gate structure 132 may serve as a gate of the third and fourth N-type transistors N3 and N4.

In the etching process, a first trench 140 extending in the second direction may be formed in the first interface region C1. In example embodiments, the first trench 140 may extend from an upper surface of the first insulating interlayer to the surface of the substrate.

In the etching process, a second trench 144 extending in the second direction may be formed in the second interface region C2. Additionally, a third trench 148 extending in the second direction may be formed in the third interface region C3. In example embodiments, the second and third trenches 144 and 148 may extend from the upper surface of the first insulating interlayer to the surface of the substrate.

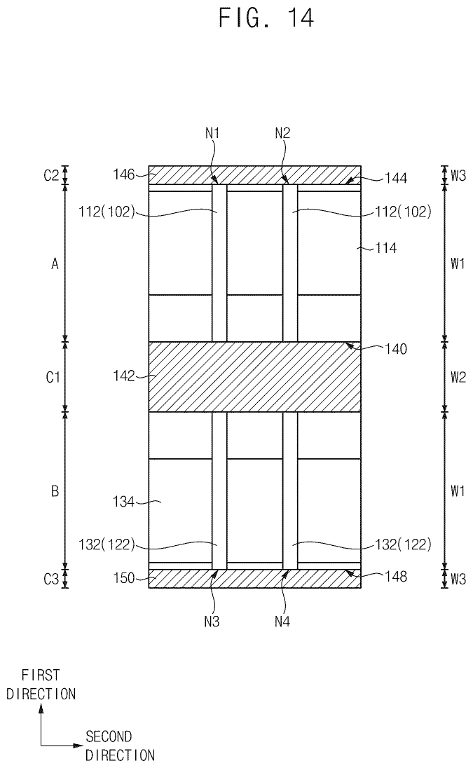

Referring to FIGS. 10 and 14, an insulation layer may be formed on the first insulating interlayer and the first to fourth gate structures 102, 112, 122 and 132 to fill the first to third trenches 140, 144, and 148. The insulation layer may be planarized until the upper surface of the first insulating interlayer is exposed to form a first insulation pattern structure 142 filling the first trench 140, a second insulation pattern structure 146 filling the second trench 144, and a third insulation pattern structure 150 filling the third trench 148. (S50)

In example embodiments, the first insulation pattern structure 142 may have the second width W2 in the first direction, and each of the second and third insulation pattern structures 146 and 150 may have the third width W3 in the first direction.

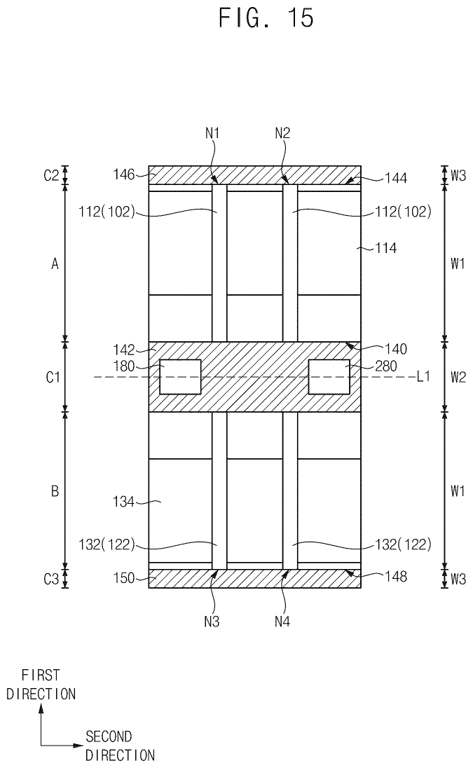

Referring to FIGS. 10 and 15, a first through via 180 and a second through via 280 extending in the vertical direction may be formed through the first insulation pattern structure 142. (S60)

Particularly, the first insulation pattern structure 142 may be etched to form first and second through-via holes, respectively. The first and second through via holes may pass through at least the first insulation pattern structure 142. In example embodiments, the first and second through via holes may extend from an upper surface of the first insulation pattern structure 142 to a portion below a lower surface of the first insulation pattern structure 142.

A conductive material may fill the first and second through via holes, so that first and second through vias 180 and 280 may be formed in the first and second through via holes, respectively.

In example embodiments, the first cell may include one first through via 180, and the second cell may include one second through via 280. Therefore, the first through via 180 and the second through via 280 may be disposed on the first interface region C1 where the first cell and the second cell face each other.

In the first interface region C1, only one through via may be disposed in the first direction. For example, the first through via 180 or the second through via 280 may be disposed on the first interface region C1 in the first direction.

In example embodiments, the first through via 180 may face the first source/drain region 106a (refer to FIG. 3) of the first P-type transistor P1. The second through via 280 may face the sixth source/drain region 126b (refer to FIG. 4) of the fourth P-type transistor P4.

In example embodiments, the first and second through vias 180 and 280 may be disposed a first straight line that passes through a center in the first direction of the first interface region C1 and extends in the second direction. At least a portion of a bottom of each of the first and second through vias 180 and 280 may contact a portion corresponding to the first straight line. In example embodiments, each of the first and second through vias 180 and 280 may be disposed on the center of the first interface region C1 in the first direction.

In example embodiments, the first and second through vias 180 and 280 may be aligned to each other in the second direction on the first straight line. Alternatively, the first and second through vias 180 and 280 may not be aligned to each other in the second direction on the first straight line.

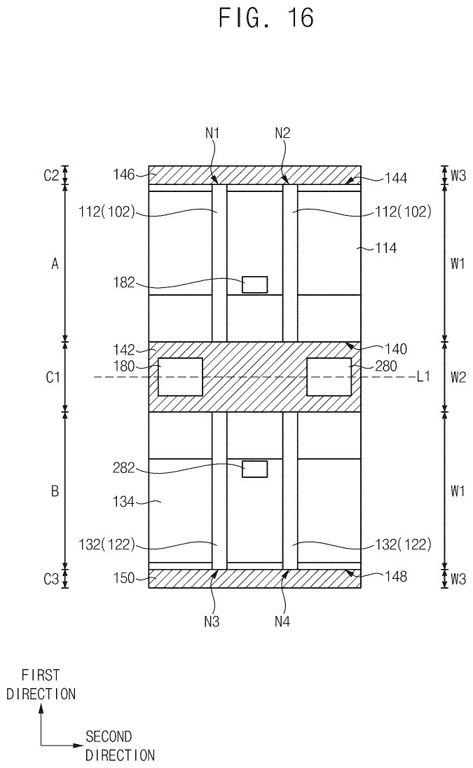

Referring to FIGS. 10 and 16, a first contact plug 182 may be formed through the first insulating interlayer to contact a second common source/drain region 116c of the first N-type and second N-type transistors N1 and N2. A second contact plug 282 may be formed through the first insulating interlayer to contact a fourth common source/drain region 136c of the third N-type and fourth N-type transistors N3 and N4. (S70)

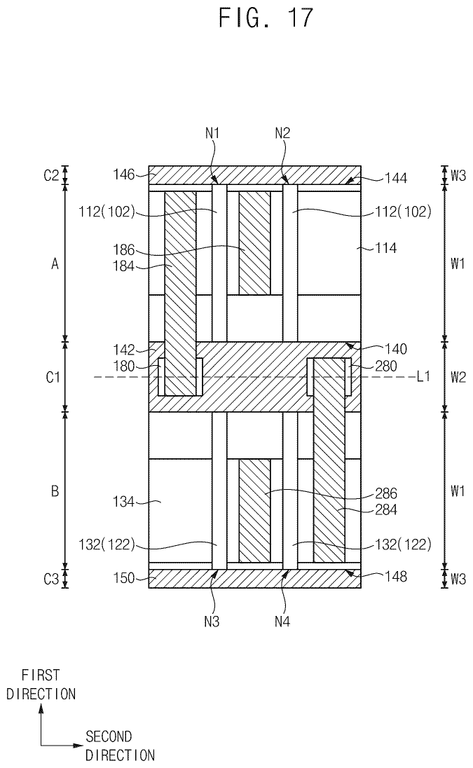

Referring to FIGS. 10 and 17, a second insulating interlayer may be formed on the first insulating interlayer. A second connection wiring 184 may be formed to contact the upper surface of the first through via 180. A third connection wiring 186 may be formed to contact the upper surface of the first contact plug 182 (refer to FIG. 16). A sixth connection wiring 284 may be formed to contact the upper surface of the second through via 280. A seventh connection wiring 286 may be formed to contact the upper surface of the second contact plug 282 (refer to FIG. 16). The second and third connection wirings 184 and 186 and the sixth and seventh connection wirings 284 and 286 may pass through the second insulating interlayer. (S80)

The second connection wiring 184 may extend in the first direction from the upper surface of the first through via 180 in the first interface region C1 into the first cell region A. The sixth connection wiring 284 may extend in the first direction from the upper surface of the second through via 280 in the first interface region C1 into the second cell region B.

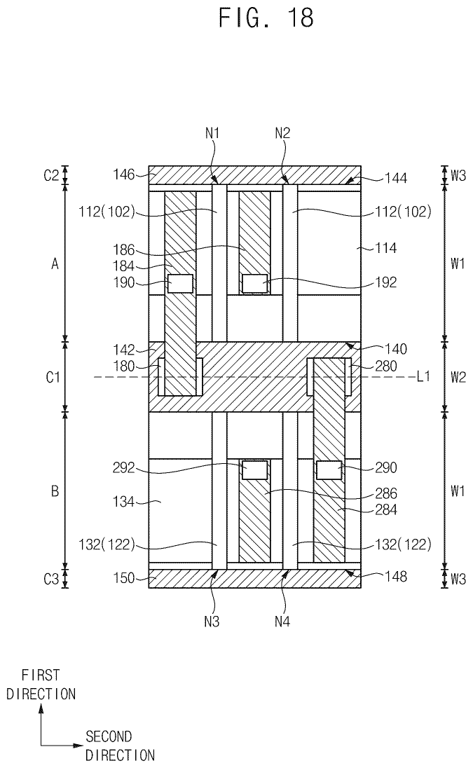

Referring to FIGS. 10 and 18, a third insulating interlayer may be formed on the second insulating interlayer. A first upper via 190 contacting the second connection wiring 184 may be formed on the second connection wiring 184. A second upper via 192 contacting the third connection wiring 186 may be formed on the third connection wiring 186. A third upper via 290 contacting the sixth connection wiring 284 may be formed on the sixth connection wiring 284. A fourth upper via 292 contacting the seventh connection wiring 286 may be formed on the seventh connection wiring 286. The first to fourth upper vias 190, 192, 290, and 292 may pass through the third insulating interlayer. (S90)

In example embodiments, the first and second upper vias 190 and 192 may be aligned to each other in the second direction. In example embodiments, the first and second upper vias 190 and 192 may be disposed on the first cell region A.

In example embodiments, the third and fourth upper vias 290 and 292 may be aligned to each other in the second direction. In example embodiments, the third and fourth upper vias 290 and 292 may be disposed on the second cell region B.

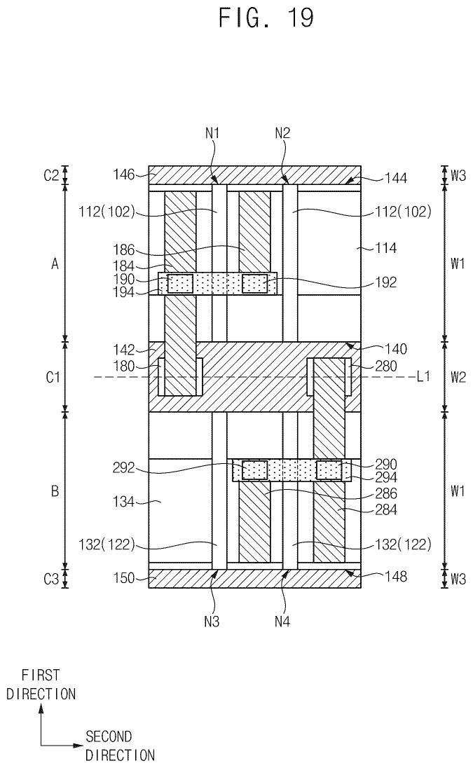

Referring to FIGS. 10 and 19, a fourth connection wiring 194 may be formed on the third insulating interlayer, the first upper via 190 and the second upper via 192, and the fourth connection wiring 194 may electrically connect the first upper via 190 and the second upper via 192. The fourth connection wiring 194 may have a line shape extending in the second direction.

An eighth connection wiring 294 may be formed on the third insulating interlayer, the third upper via 290 and the fourth upper via 292, and the eighth connection wiring 294 may electrically connect the third upper via 290 and the fourth upper via 292. The eighth connection wiring 294 may have a line shape extending in the second direction. (S100)

Thereafter, an upper insulating interlayer may be formed to cover the third insulating interlayer, the fourth connection wiring 194, and the eighth connection wiring 294.

Referring to FIG. 10, a carrier substrate may be attached on the upper insulating interlayer. A bottom surface of the substrate may be ground by a grinding process. In the grinding process, most of the substrate may be removed, and bottoms of the first and second through vias 180 and 280 may be exposed.

A first connection wiring 170 (refer to FIG. 3) may be formed to connect the bottom of the first through via 180 and the first source/drain region 106a (refer to FIG. 3) of the first P-type transistor P1. The first connection wiring 170 may contact the bottom of the first through via 180, and may extend in the first direction from the bottom surface of the first through via 180 to inside of the first cell region A.

A fifth connection wiring 270 (refer to FIG. 4) may be formed to connect the bottom of the second through via 280 and the sixth source/drain region 126b (refer to FIG. 4) of the fourth P-type transistor P4. The fifth connection wiring 270 may contact the bottom of the second through via 280, and may extend in the first direction from the bottom of the second through via 280 to inside of the second cell region B. (S110)

Thereafter, a lower support layer 50 (refer to FIGS. 7 to 9) may cover the first and fifth connection wirings 170 and 270 and lower portions of the first-floor transistors P1, P2, P3, and P4. The lower support layer 50 may include an insulation material.

By the above process, the semiconductor device shown in FIG. 2A may be manufactured. The semiconductor device may include the first cell 10 (refer to FIG. 2A) on the first cell region A and the second cell 20 (refer to FIG. 2A) on the second cell region B. The first through via 180 included in the first cell 10 and the second through via 280 included in the second cell 20 may be disposed on the interface region C1.

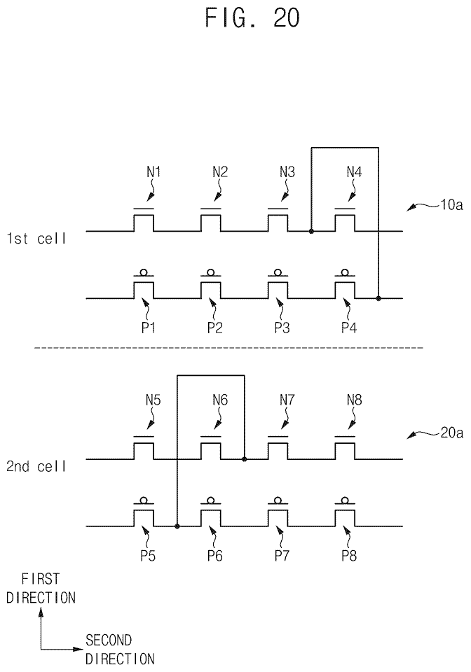

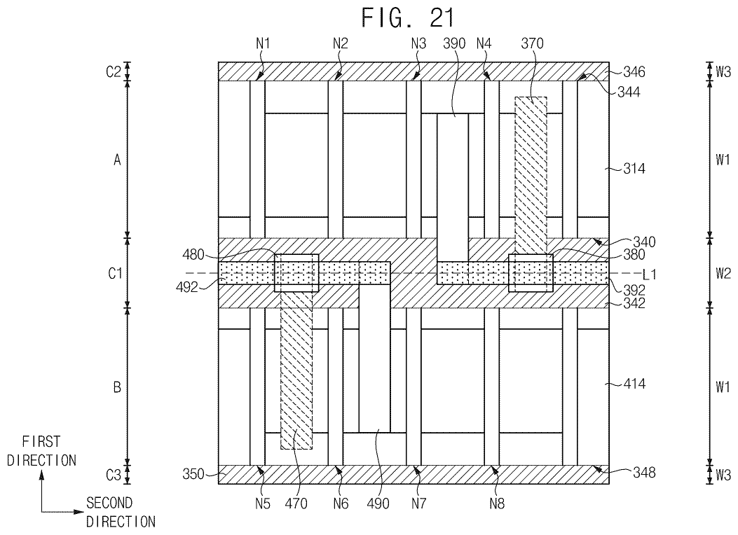

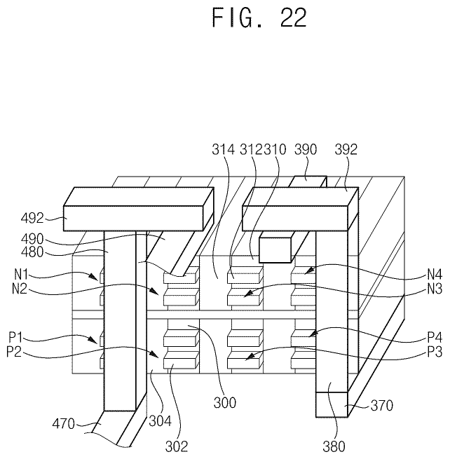

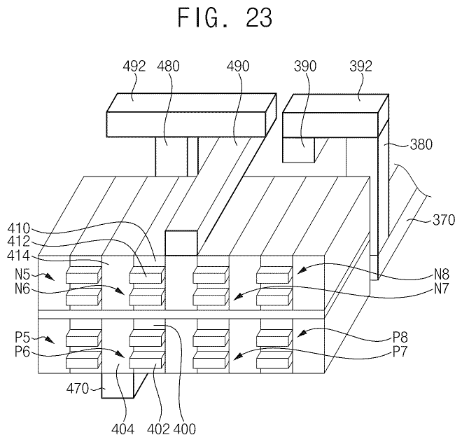

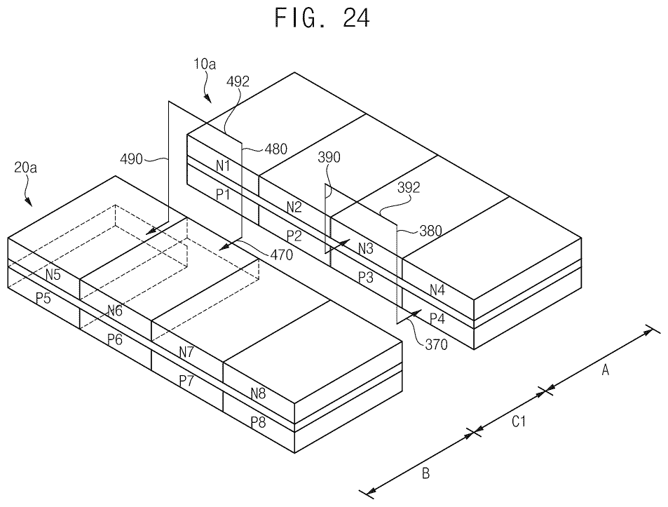

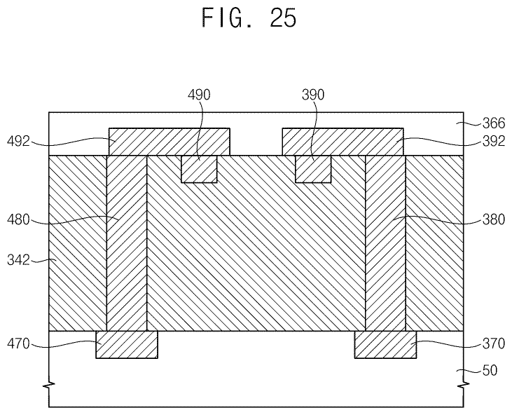

FIG. 20 is a circuit diagram of first and second cells of a semiconductor device according to example embodiments. FIG. 21 is a schematic plan view illustrating connection wirings of each of a plurality of cells of a semiconductor device according to example embodiments. FIG. 22 is a schematic perspective view of a first cell of a semiconductor device according to example embodiments. FIG. 23 is a schematic perspective view of a second cell of a semiconductor device according to example embodiments. FIG. 24 is a schematic perspective view illustrating connection wirings of each of a plurality of cells of a semiconductor device according to example embodiments. FIG. 25 is a schematic cross-sectional view of a semiconductor device according to example embodiments.

First, with reference to FIG. 20, each of first and second cells 10a and 20a, respectively, included in the semiconductor device may be described.

Referring to FIG. 20, the semiconductor device may include the first cell 10a and the second cell 20a.

The first cell 10a may include at least four P-type transistors P1, P2, P3, and P4 and at least four N-type transistors N1, N2, N3, and N4. The P-type transistors included in the first cell 10a are referred to as first to fourth P-type transistors P1, P2, P3, and P4, respectively. The N-type transistors included in the first cell 10a are referred to as first to fourth N-type transistors N1, N2, N3, and N4, respectively.

The first to fourth P-type transistors P1, P2, P3, and P4 may be connected in series. Each of the first to fourth P-type transistors P1, P2, P3, and P4 may include a gate structure and source/drain regions. The first and second P-type transistors P1 and P2 may include a first common source/drain region, the second and third P-type transistors P2, P3 may include a second common source/drain region, and the third and fourth P-type transistors P3 and P4 may include a third common source/drain region.

The first to fourth N-type transistors N1, N2, N3, and N4 may be connected in series. Each of the first to fourth N-type transistors N1, N2, N3, and N4 may include a gate structure and source/drain regions. The first and second N-type transistors N1 and N2 may include a fourth common source/drain region, the second and third N-type transistors N2 and N3 may include a fifth common source/drain region, and the third and fourth N-type transistors N3 and N4 may include a sixth common source/drain region.

The source/drain region of the P-type transistor P4 may be electrically connected to the sixth common source/drain region of the third and fourth N-type transistors N3 and N4.

The second cell 20a may be adjacent to the first cell 10a in the first direction. The second cell 20a may be spaced apart from the first cell 10a in the first direction.

The second cell 20a may have circuits substantially the same as circuits of the first cell 10a. However, positions of connection wirings in the second cell 20a may be different from positions of connection wirings in the first cell 10a. The second cell 20a may have a shape in which the first cell 10a is rotated by 180 degrees. The first cell 10a and the second cell 20a may operate independently.

The second cell 20a may include at least four P-type transistors P5, P6, P7, and P8 and at least four N-type transistors N5, N6, N7, and N8. The P-type transistors included in the second cell 20a are referred to as fifth to eighth P-type transistors P5, P6, P7, and P8, respectively. The N-type transistors included in the first cell 10a are referred to as fifth to eighth N-type transistors N5, N6, N7, and N8, respectively.

The fifth to eighth P-type transistors P5, P6, P7, and P8 may be connected in series. The fifth to eighth P-type transistors P5, P6, P7, and P8 may include a gate structure and source/drain regions. The fifth and sixth P-type transistors P5 and P6 may include a seventh common source/drain region, the sixth and seventh P-type transistors P6 and P7 may include an eighth common source/drain region, and the seventh and eighth P-type transistors P7 and P8 may include a ninth common source/drain region.

The fifth to eighth N-type transistors P5, P6, P7, and P8 may be connected in series. The fifth to eighth P-type transistors P5, P6, P7, and P8 may include a gate structure and source/drain regions. The fifth and sixth N-type transistors N5 and N6 may include a tenth common source/drain region, the sixth and seventh N-type transistors N6 and N7 may include an eleventh common source/drain region, and the seventh and eighth N-type transistors N7 and N8 may include a twelfth common source/drain region.

The seventh common source/drain region of the fifth and sixth P-type transistors P5 and P6 may be electrically connected to the eleventh common source/drain region of the sixth and seventh N-type transistors N6 and N7.

Hereinafter, a semiconductor device including the circuits shown in FIG. 20 and implemented on the lower support layer is described.

Referring to FIGS. 21 to 25, the first cell 10a and the second cell 20a may be disposed on the lower support layer 50.

The lower support layer 50 may have the first cell region A where transistors included in the first cell 10a are disposed, the second cell region B where transistors included in the second cell 20a are disposed, the first interface region C1 between the first and second cell regions A and B, the second interface region C2 outside and adjacent (in the first direction) the first cell region A, and the third interface region C3 outside and adjacent (in the first direction) the cell region B.

Each of the first and second cell regions A and B may have a first width W1 in the first direction. The first interface region C1 may have a second width W2 in the first direction, and each of the second and third interface regions C2 and C3 may have a third width W3 in the first direction. The second width W2 and the third width W3 may be different from each other. In example embodiments, the second width W2 may be greater than the third width W3. In example embodiments, the first width W1 may be greater than the second width W2.

The first to fourth P-type transistors P1, P2, P3 and P4 and first to fourth N-type transistors N1, N2, N3 and N4 may be disposed on the first cell region A. The fifth to eighth P-type transistors P5, P6, P7 and P8 and the fifth to eighth N-type transistors N5, N6, N7 and N8 may be disposed on the second cell region B.

In example embodiments, the first to fourth N-type transistors N1, N2, N3 and N4 may be disposed over the first to fourth P-type transistors P1, P2, P3 and P4. In example embodiments, the first P-type transistor P1 and the first N-type transistor N1 may be aligned to each other in the vertical direction. The second P-type transistor P2 and the second N-type transistor N2 may be aligned to each other in the vertical direction. The third P-type transistor P3 and the third N-type transistor N3 may be aligned to each other in the vertical direction. The fourth P-type transistor P4 and the fourth N-type transistor N4 may be aligned to each other in the vertical direction.

Each of the first to fourth P-type transistors P1, P2, P3 and P4 may include a first nanosheet structure 300, a first gate structure 302, and a first semiconductor structure 304. Each of the first to fourth N-type transistors N1, N2, N3 and N4 may include a second nanosheet structure 310, a second gate structure 312, and a second semiconductor structure 314.

In example embodiments, the fifth to eighth N-type transistors N5, N6, N7 and N8 may be disposed over the fifth to eighth P-type transistors P5, P6, P7 and P8. In example embodiments, the fifth P-type transistor P5 and the fifth N-type transistor N5 may be aligned to each other in the vertical direction. The sixth P-type transistor P6 and the sixth N-type transistor N6 may be aligned to each other in the vertical direction. The seventh P-type transistor P7 and the seventh N-type transistor N7 may be aligned to each other in the vertical direction. The eighth P-type transistor P8 and the eighth N-type transistor N8 may be aligned to each other in the vertical direction.

Each of the fifth to eighth P-type transistors P5, P6, P7 and P8 may include a third nanosheet structure 400, a third gate structure 402, and a third semiconductor structure 404. Each of the fifth to eighth N-type transistors N5, N6, N7 and N8 may include a fourth nanosheet structure 410, a fourth gate structure 412, and a fourth semiconductor structure 414.

A first insulation pattern structure 342 may be disposed on the first interface region C1.

In example embodiments, a first trench 340 formed by a gate cutting process for forming the first and third gate structures 302 and 402 and the second and fourth gate structures 312 and 412 may be disposed on the first interface region C1. The first trench 340 may extend in the second direction. The first insulation pattern structure 342 may fill the first trench 340.

The first insulation pattern structure 342 may extend in the vertical direction from a portion above upper surfaces of uppermost second and fourth gate structures 312 and 412 to a portion below bottom of lowermost first and third gate structures 302 and 402. The first insulation pattern structure 342 may extend in the second direction.

A second trench 344 may be disposed on the second interface region C2, and a second insulation pattern structure 346 may fill the second trench 344. A third trench 348 may be disposed on the third interface region C3, and a third insulation pattern structure 350 may fill the third trench 348.

In the first cell region A and the second cell region B, a first insulating interlayer may be disposed to cover transistors included in the first cell 10a and transistors included in the second cell 20a. An upper insulating interlayer 366 may be disposed on the first insulating interlayer and the first insulation pattern structure 342.

A first connection wiring 370 may contact the source/drain region of the fourth P-type transistor P4, and the first connection wiring 370 may extend horizontally in a first direction from the source/drain region of the fourth P-type transistor P4 to the inside of the first interface region C1. One end of the first connection wiring 370 may be disposed in the first cell region A, and the other end of the first connection wiring 370 may be disposed in the first interface region C1.

In example embodiments, the first connection wiring 370 may contact a bottom of the first semiconductor structure 304 serving as the source/drain region of the fourth P-type transistor P4. Alternatively, the first connection wiring 370 may contact a sidewall of the first semiconductor structure 304 serving as the source/drain region of the fourth P-type transistor P4.

In example embodiments, the other end of the first connection wiring 370 may be positioned between a center of the first insulation pattern structure 342 in the first direction and a third edge of the second cell region B. In example embodiments, a portion of the first connection wiring 370 may overlap a first through via 380.

The first through via 380 may pass through the first insulation pattern structure 342, and may extend in the vertical direction to the upper surface of the first connection wiring 370. In example embodiments, an upper surface of the first through via 380 may be coplanar with the upper surface of the first insulation pattern structure 342. In example embodiments, the upper surface of the first through via 380 may be coplanar with an upper surface of the first insulating interlayer.

The first through via 380 may be a maximum through plug passing through the first insulation pattern structure 342.

In example embodiments, the upper surface of the first through via 380 may be higher than upper portions of the first to fourth N-type transistors N1, N2, N3 and N4, relative to the upper surface of the lower support layer 50 as a reference layer. The bottom of the first through via 380 may contact the upper surface of the first connection wiring 370. In example embodiments, the bottom of the first through via 380 may be lower than a bottom of a lowermost gate structure of the first to fourth P-type transistors P1, P2, P3 and P4, relative to the upper surface of the lower support layer 50.

The first through via 380 may be positioned on a first straight line that passes through a center in the first direction of the first the interface region Cl and extends in the second direction. At least a portion of the bottom of the first through via 380 may contact a portion corresponding to the first straight line. Accordingly, in a cross-sectional view taken along a line extending in the second direction and passing the center of the first interface region C1 in the first direction, the first through via 380 may be shown.

In example embodiments, the first through via 380 may be positioned at the center of the first interface region C1 in the first direction.

A second connection wiring 390 may be disposed on the second semiconductor structure 314 corresponding to the third common source/drain region of the third N-type and fourth N-type transistors. The second connection wiring 390 may be electrically connected to the third common source/drain region.

The second connection wiring 390 may pass through the first insulating interlayer and may contact the upper surface of the second semiconductor structure 314. In example embodiments, an upper surface of the second connection wiring 390 may be coplanar with the upper surface of the first insulating interlayer. The upper surface of the second connection wiring 390 and the upper surface of the first through via 380 may be coplanar with each other.

A third connection wiring 392 may extend in the second direction while contacting the upper surface of the first through via 380 and the upper surface of the second connection wiring 390. The third connection wiring 392 may be disposed on the first interface region C1.

Hereinafter, connection structures of the fifth to eighth P-type transistors P5, P6, P7 and P8 and the connection structure of the fifth to eighth N-type transistors N5, N6, N7 and N8 may be described. The connection structures of the second cell 20a may be substantially the same as the connection structures of the first cell 10a rotated by 180 degrees.

A fourth connection wiring 470 may contact the source/drain region of the fifth P-type transistor P5, and may extend horizontally in the first direction from the source/drain region of the fifth P-type transistor P5 to the inside of the first interface region C1. One end of the fourth connection wiring 470 may be positioned in the second cell region B, and the other end of the fourth connection wiring 470 may be positioned in the first interface region C1.

In example embodiments, the fourth connection wiring 470 may contact the bottom of the third semiconductor structure 404 serving as the seventh common source/drain region of the fifth and sixth P-type transistors P5 and P6.

In example embodiments, the other end of the fourth connection wiring 470 may be positioned between the center of the first insulation pattern structure 342 in the first direction and the first edge of the first cell region A. In example embodiments, a portion of the fourth connection wiring 470 may overlap a second through via 480.

The second through via 480 may pass through the first insulation pattern structure 342, and may extend in the vertical direction to an upper surface of the fourth connection wiring 470. In example embodiments, the upper surface of the second through via 480 may be coplanar with the upper surface of the first insulation pattern structure 342. In example embodiments, the upper surface of the second through via 480 may be coplanar with the upper surface of the first insulating interlayer.

The second through via 480 may be a maximum through plug passing through the first insulation pattern structure 342.

In example embodiments, the second through via 480 may have the same shape as the first through via 380. For example, the second through via 480 may have a diameter substantially the same as a diameter of the first through via 380. The second through via 480 may have a height substantially the same as a height of the first through via 380.

In example embodiments, the upper surface of the second through via 480 may be higher than upper portions of the fifth to eighth N-type transistors N5, N6, N7 and N8, relative to the upper surface of the lower support layer 50 as a reference layer. A bottom of the second through via 480 may contact the upper surface of the fourth connection wiring 470. In example embodiments, the bottom of the second through via 480 may be lower than bottoms of the lowermost gate structures of the fifth to eighth P-type transistors P5, P6, P7 and P8, relative to the upper surface of the lower support layer 50.

The second through via 480 may be positioned on the first straight line that passes through the center in the first direction of the first interface region C1 and extends in the second direction. At least a portion of the bottom of the second through via 480 may contact a portion corresponding to the first straight line. Accordingly, in a cross-sectional view cut in the second direction so as to pass through the center of the first interface region C1 in the first direction, the first and second through vias 380 and 480 may be shown.

In example embodiments, the first and second through vias 380 and 480 on the first straight line may be aligned to each other in the second direction. Alternatively, the first and second through vias 380 and 480 on the first straight line may not be aligned to each other in the second direction.

In example embodiments, the second through via 480 may be positioned at the center of the first interface region C1 in the first direction.

A fifth connection wiring 490 may be positioned on the fourth semiconductor structure 414 corresponding to the eleventh common source/drain region of the sixth N-type and seventh N-type transistors N6 and N7. The fifth connection wiring 490 may be electrically connected to the fourth common source/drain region.

The fifth connection wiring 490 may pass through the first insulating interlayer, and may contact an upper surface of the fourth semiconductor structure 414. In example embodiments, an upper surface of the fifth connection wiring 490 may be coplanar with the upper surface of the first insulating interlayer. The upper surface of the fifth connection wiring 490 and the upper surface of the second through via 480 may be coplanar with each other.

A sixth connection wiring 492 may extend in the second direction while contacting the upper surface of the second through via 480 and the upper surface of the fifth connection wiring 490. The sixth connection wiring 492 may be disposed on the first interface region C1.

As described above, one first cell 10a may include one first through via 380, and one second cell may include one second through via 480. The first through via 380 and the second through via 480 may be disposed on the first interface region C1 between the first cell region A and the second cell region B.

Additionally, the third connection wiring 392 contacting the first through via 380 and extending in the second direction and a sixth connection wiring 492 contacting the second through via 480 and extending in the second direction may be disposed on the first interface region C1. In the first interface region C1, one end of the third connection wiring 392 and one end of the sixth connection wiring 492 may be spaced apart from each other. The one end of the third connection wiring 392 and the one end of the sixth connection wiring 492 may face to each other in the second direction.

The first through via 380 and the second through via 480 may be disposed on the center of the first interface region C1 in the first direction, so that a second width W2 of the first interface region C1 required to form the first and second through vias 380 and 480 may be decreased.

While the present inventive concepts have been shown and described with reference to example embodiments thereof, it will be understood by those of ordinary skill in the art that various changes in form and details may be made thereto without departing from the scope of the present inventive concepts as set forth by the following claims.

What is claimed is:

1. A semiconductor device, comprising:
first P-type transistors on a lower support layer of a first cell region;
first N-type transistors over the first P-type transistors;
second P-type transistors on the lower support layer of a second cell region spaced apart from the first cell region in a first direction parallel to an upper surface of the lower support layer;
second N-type transistors over the second P-type transistors;
an insulation pattern structure on a first interface region between the first and second cell regions;
a first through via extending in the insulation pattern structure, the first through via on a central portion of the first interface region in the first direction;
a second through via extending in the insulation pattern structure, the second through via on the central portion of the first interface region in the first direction, and the second through via spaced apart from the first through via in a second direction parallel to the upper surface of the lower support layer and perpendicular to the first direction;
a first wiring group electrically connected to the first through via, the first wiring group electrically connecting one of the first N-type transistors and one of the first P-type transistors; and
a second wiring group electrically connected to the second through via, the second wiring group electrically connecting one of the second N-type transistors and one of the second P-type transistors.

2. The semiconductor device of claim 1, wherein the first cell region and the second cell region have same dimensions in the first and second directions, and the first cell region and the second cell region face each other in the first direction.

3. The semiconductor device of claim 1, further comprising a second interface region outside the first cell region and facing the first interface region, and a third interface region outside the second cell region and facing the first interface region,
wherein a width in the first direction of the first interface region is different from a width in the first direction of each of the second interface region and third interface region.

4. The semiconductor device of claim 3, wherein the width in the first direction of the first interface region is greater than the width in the first direction of each of the second interface region and third interface region.

5. The semiconductor device of claim 1, wherein upper surfaces of the first through via and the second through via are higher than upper surfaces of uppermost gate structures in the first and second N-type transistors relative to the upper surface of the lower support layer, and bottoms of the first through via and the second through via are lower than bottoms of lowermost gate structures in the first and second N-type transistors relative to the upper surface of the lower support layer.

6. The semiconductor device of claim 1, wherein a diameter of each of the first through via and the second through is the same, and
wherein a width in the first direction of the first interface region is about 110% to 300% of the diameter of each of the first through via and the second through via.

7. The semiconductor device of claim 1, wherein the first through via and the second through via are aligned to each other in the second direction.

8. The semiconductor device of claim 1, wherein the first N-type transistors are spaced apart from the first P-type transistors in a vertical direction perpendicular to the upper surface of the lower support layer, and the first N-type transistors and the first P-type transistors are aligned to each other in the vertical direction, and
wherein the second N-type transistors are spaced apart from the second P-type transistors in the vertical direction, and the second N-type transistors and the second P-type transistors are aligned to each other in the vertical direction.

9. The semiconductor device of claim 1, wherein the first P-type transistors and the second P-type transistors are aligned to each other in the first direction, and
wherein the first N-type transistors and the second N-type transistors are aligned to each other in the first direction.

10. The semiconductor device of claim 1, wherein the second wiring group and the second through via have a shape of the first wiring group and the first through via, respectively, rotated by 180 degrees.

11. The semiconductor device of claim 1, wherein the first wiring group includes:
a first connection wiring electrically connecting a source/drain region of one of the first P-type transistors and a bottom of the first through via;
a second connection wiring contacting an upper surface of the first through via, and the second connection wiring extending in the first direction from the first interface region to the first cell region;
a third connection wiring contacting a source/drain region of one of the first N-type transistors;
a first upper via contacting an upper surface of the second connection wiring;
a second upper via contacting an upper surface of the third connection wiring; and
a fourth connection wiring electrically connecting upper surfaces of the first upper via and the second upper via, the fourth connection wiring extending in the second direction, and
wherein the second wiring group includes:
a fifth connection wiring electrically connecting a source/drain region of one of the second P-type transistors and a bottom of the second through via;
a sixth connection wiring contacting an upper surface of the second through via, and the sixth connection wiring extending in the first direction from the first interface region to the second cell region;
a seventh connection wiring contacting a source/drain region of one of the second N-type transistors;
a third upper via contacting an upper surface of the sixth connection wiring;
a fourth upper via contacting an upper surface of the seventh connection wiring; and
an eighth connection wiring electrically connecting upper surfaces of the third upper via and the fourth upper via, the eighth connection wiring extending in the second direction.

12. The semiconductor device of claim 1, wherein the first wiring group includes:
a first connection wiring electrically connecting a source/drain region of one of the first P-type transistors and a bottom of the first through via;
a second connection wiring contacting a source/drain region of one of the first N-type transistors, the second connection wiring extending in the first direction from the first cell region to the first interface region; and
a third connection wiring on the first and second connection wirings in the first interface region, the third connection wiring electrically connecting the first connection wiring and the second connection wiring, the third connection wiring extending in the second direction,
and wherein the second wiring group includes:
a fourth connection wiring electrically connecting a source/drain region of one of the second P-type transistors and a bottom of the second through via;
a fifth connection wiring contacting a source/drain region of one of the second N-type transistors, the fifth connection wiring extending in the first direction from the second cell region to the first interface region; and
a sixth connection wiring on the fourth and fifth connection wirings in the first interface region, the sixth connection wiring electrically connecting the fourth connection wiring and fifth connection wiring, the sixth connection wiring extending in the second direction.

13. The semiconductor device of claim 12, wherein one end of the third connection wiring and one end of the sixth connection wiring are spaced apart from each other in the first direction and/or the second direction, and
wherein the third connection wiring and the sixth connection wiring are aligned to each other in the second direction.

14. A semiconductor device, comprising:
a lower support layer including a first cell region, a second cell region, and a first interface region between the first and second cell regions, a second interface region outside the first cell region, and a third interface region outside the second cell region;
first cell transistors including first P-type transistors and first N-type transistors, the first P-type transistors on the first cell region of the lower support layer, and the first N-type transistors spaced apart from the first P-type transistors in a vertical direction perpendicular to an upper surface of the lower support layer;
second cell transistors including second P-type transistors and second N-type transistors, the second P-type transistors on the second cell region of the lower support layer, and the second N-type transistors spaced apart from the second P-type transistors in the vertical direction;
a first through via on the first interface region, an upper surface of the first through via being higher than an upper surface of a gate structure of an uppermost first cell transistor among the first cell transistors relative to the upper surface of the lower support layer, and a bottom of the first through via being lower than a bottom of a gate structure of a lowermost first cell transistor among the first cell transistors relative to the upper surface of the lower support layer;
a second through via on the first interface region, the second through via having a shape that is the same as a shape of the first through via along at least one dimension;
a first wiring group electrically connected to the first through via, the first wiring group electrically connecting at least a subset of the first cell transistors to each other; and
a second wiring group electrically connected to the second through via, the second wiring group electrically connecting at least a subset of the second cell transistors to each other.

15. The semiconductor device of claim 14, wherein a width in a first direction, parallel to the upper surface of the lower support layer, of the first interface region is greater than a width in the first direction of each of the second interface region and the third interface region.

16. The semiconductor device of claim 14, wherein a first edge of the first interface region in a first direction, parallel to the upper surface of the lower support layer, contacts one end of gate structures of each of the first cell transistors, and a second edge facing the first edge of the first interface region contacts one end of gate structures of each of the second cell transistors.

17. The semiconductor device of claim 14, wherein each of the first through via and the second through via is at a central portion of the first interface region in a first direction parallel to the upper surface of the lower support layer.

18. A semiconductor device, comprising:
first cell transistors on a first cell region;
second cell transistors on a second cell region spaced apart from the first cell region in a first direction parallel to an upper surface of the semiconductor device, dimensions of the second cell region being equal to dimensions of the first cell region in the first direction and a second direction parallel to the upper surface of the semiconductor device and perpendicular to the first direction;
a first wiring group electrically connecting at least a subset of the first cell transistors to each other, the first wiring group including a first through via and first wirings contacting an upper portion and a lower portion of the first through via; and
a second wiring group electrically connecting at least a subset of the second cell transistors to each other, the second wiring group including a second through via and second
wirings contacting an upper portion and a lower portion of the second through via, wherein each of the first through via and the second through via is on the central portion of a first interface region between the first cell region and the second cell region in the first direction.

19. The semiconductor device of claim 18, wherein a shape of the second wiring group is the same as a shape of the first wiring group rotated by 180 degrees.

20. The semiconductor device of claim 18, wherein a diameter of the first through via and a diameter of the second through via are equal, and
wherein a width in the first direction of the first interface region is about 110% to 300% of the diameter of each of the first through via and the second through via.
